(19) United States
(12) Patent Application Publication
(10) Pub. No.: US 2025/0358992 A1
(43) Pub. Date: Nov. 20, 2025

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/663,372

(22) Filed: May 14, 2024

(51) Int. Cl. H10B 10/00; H01L 21/762; H01L 29/06; H01L 29/417; H01L 29/423; H01L 29/66

(52) U.S. Cl. CPC H10B 10/12; H01L 21/76224; H10D 30/6729; H10D 30/6735; H10D 62/121; H10D 64/017

(57) ABSTRACT

A semiconductor structure includes a first transistor, a second transistor, a gate structure, and a first dielectric layer. The first transistor over a substrate includes first nanostructures and first source/drain features. The first nanostructures are spaced apart from each other in a Z-direction. The first source/drain features are on opposite sides of the first nanostructures in an X-direction. The second transistor over the first transistor includes second nanostructures and second source/drain features. The second nanostructures are spaced apart from each other in the Z-direction. The second nanostructures are over the first nanostructures. The second source/drain features are on opposite sides of the second nanostructures in the X-direction. The second source/drain features are over the first source/drain features. The gate structure wraps around the first nanostructures and the second nanostructures. The first dielectric layer is under the gate structure, the first nanostructures, and the second nanostructures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce the chip footprint while maintaining reasonable processing margins.

As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIG. 5 is a perspective view of a workpiece at a fabrication stage, in accordance with some embodiments of the present disclosure.

FIGS. 6, 7, 8B, 21B, 22B, 23B, and 24B are Y-Z cross-sectional views of the workpiece at various fabrication stages along a line A-A′ of FIG. 5, in accordance with some embodiments of the present disclosure.

FIGS. 8A, 9A, 10A, 11A, 12A, 13A, 14A, 15A, 16A, 17A, 18A, 19A, 20A, and 25B are Y-Z cross-sectional views of the workpiece at various fabrication stages along a line B-B′ of FIG. 5, in accordance with some embodiments of the present disclosure.

FIGS. 9B, 10B, 11B, 12B, 13B, 14B, 15B, 16B, 17B, 18B, 19B, 20B, 21A, 22A, 23A, 24A, and 25A are X-Z cross-sectional views of the workpiece at various fabrication stages along a line C-C′ of FIG. 5, in accordance with some embodiments of the present disclosure.

FIG. 26A is an X-Z cross-sectional view of the workpiece at the fabrication stage shown in FIG. 25A, in accordance with some alternative embodiments of the present disclosure.

FIG. 26B is a Y-Z cross-sectional view of the workpiece at the fabrication stage shown in FIG. 25B, in accordance with some alternative embodiments of the present disclosure.

FIGS. 27A and 27B are X-Z cross-sectional views of the workpiece at the fabrication stages shown in FIGS. 10B and 25A, in accordance with some alternative embodiments of the present disclosure.

FIGS. 28A and 28B are X-Z cross-sectional views of the workpiece at the fabrication stages shown in FIGS. 10B and 25A, in accordance with some alternative embodiments of the present disclosure.

FIGS. 29B and 34B are Y-Z cross-sectional views of the workpiece at a fabrication stage along the line A-A′ of FIG. 5, in accordance with some alternative embodiments of the present disclosure.

FIGS. 29A, 30A, and 31A are Y-Z cross-sectional views of the workpiece at various fabrication stages along the line B-B′ of FIG. 5, in accordance with some alternative embodiments of the present disclosure.

FIGS. 30B, 31B, 32, 33, and 34A are X-Z cross-sectional views of the workpiece at various fabrication stages along the line C-C′ of FIG. 5, in accordance with some alternative embodiments of the present disclosure.

FIGS. 35, 36, and 37 are X-Z cross-sectional views of the workpiece at the fabrication stage shown in FIG. 25A, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures, in memory (e.g., SRAM) and/or standard logic cells of an integrated circuit (IC) structure. Generally, a complementary field-effect transistor (CFET) may include a n-type FET (NFET) and a p-type FET (PFET) disposed vertically with a plurality of vertically stacked sheets (e.g., nanosheets), wires (e.g., nanowires), or rods (e.g., nanorods) in a channel region of the CFET, thereby allowing better gate control, lowered leakage current, and improved scaling capability for various IC applications. While existing technologies for fabricating CFETs have been generally adequate for their intended applications, they have not been entirely satisfactory in all aspects.

The gate-all-around (GAA) structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including CFET with a dielectric layer under the gate structure and nanostructures to enhance performance. The details of the structure and fabrication methods of the present disclosure are described below in conjunction with the accompanying drawings, which illustrate the processes and the structures for CFET, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

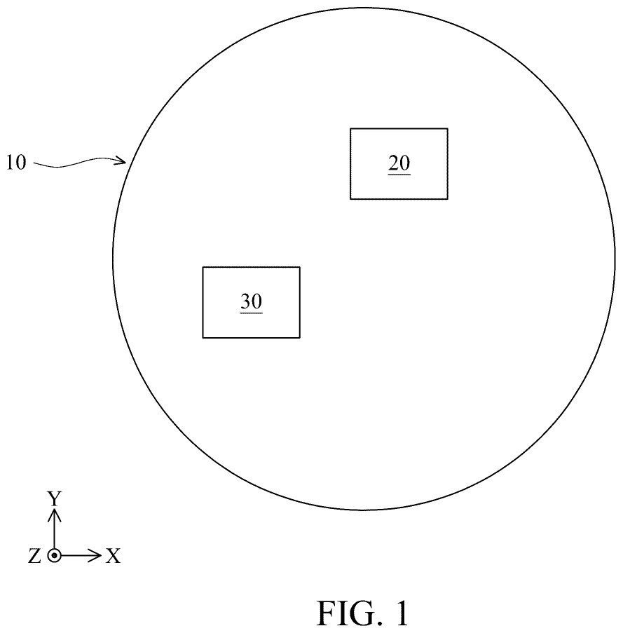

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

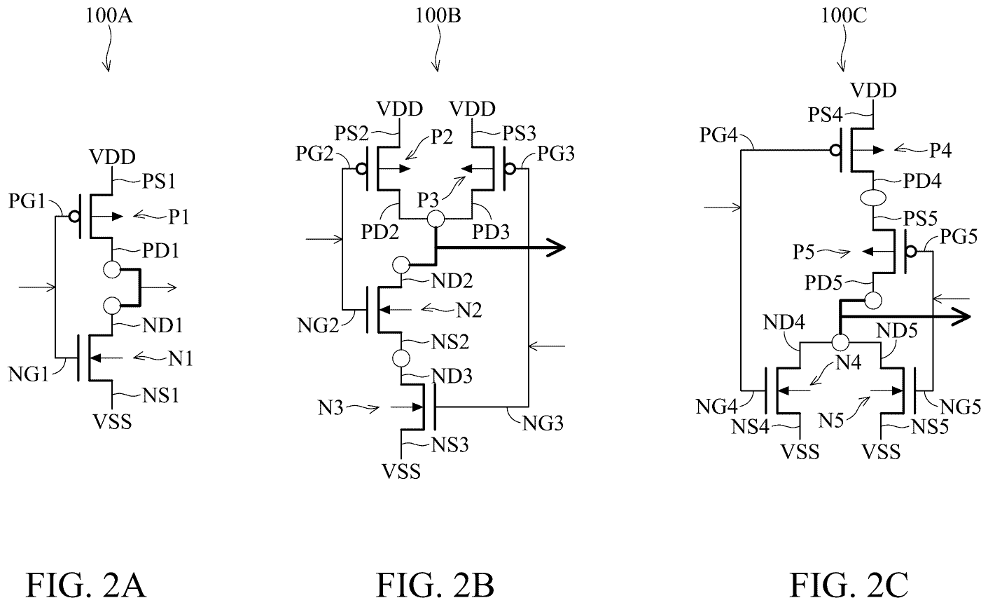

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as a “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

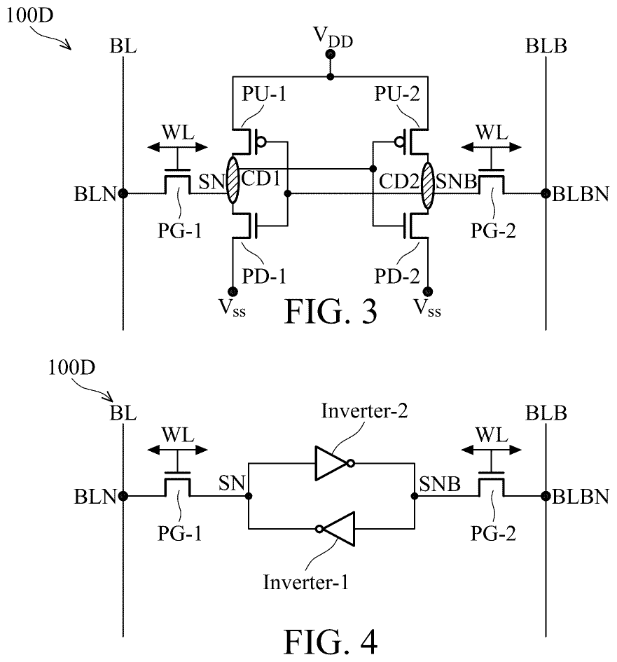

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) V_{DD}, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) V_{SS}, and the first common drain.

A gate of pull-up transistor PU-2 interposes a source, which is electrically coupled to the first power supply voltage via voltage node V_{DD}, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node V_{SS}, and the second common drain.

The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary CFET for the circuit cells and the SRAM cells discussed above are illustrated and described below. More specifically, the manufacturing method and the structure of CFETs with improved dielectric layer under nanostructures and gate structure for the circuit cells and the SRAM cells discussed above are illustrated and described below. However, it should be understood that the application should not be limited to a particular type of device, except as specifically claimed.

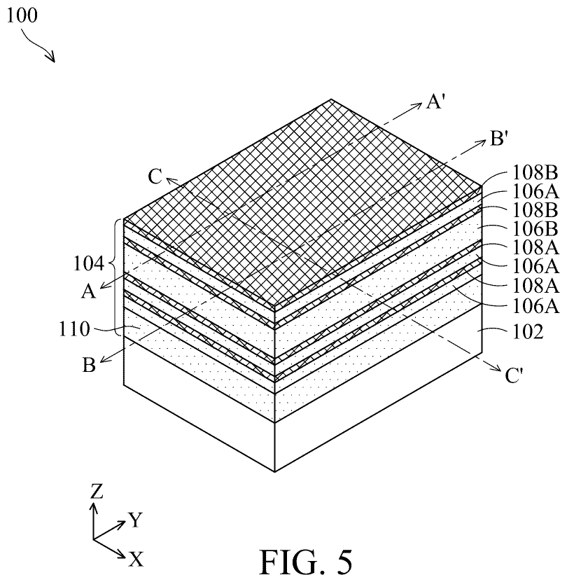

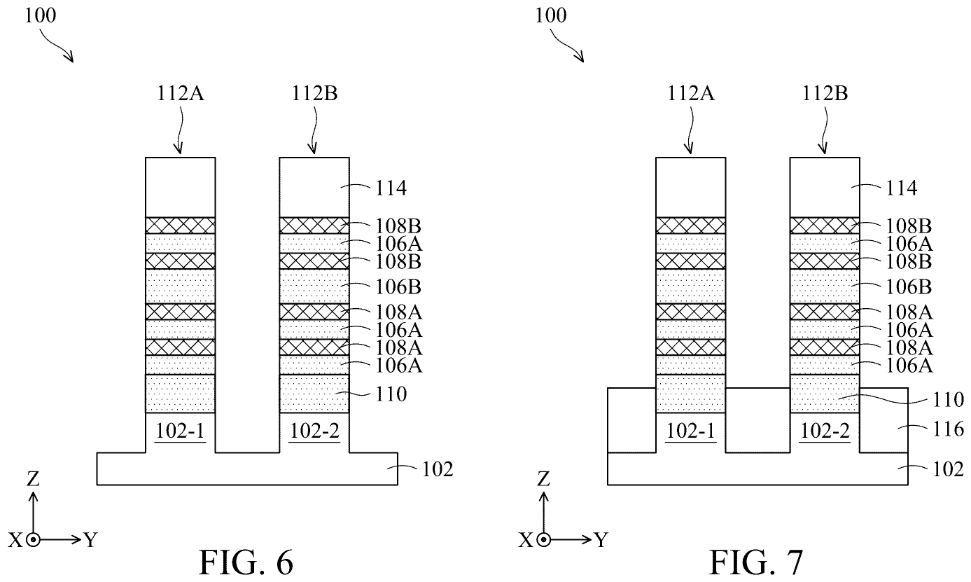

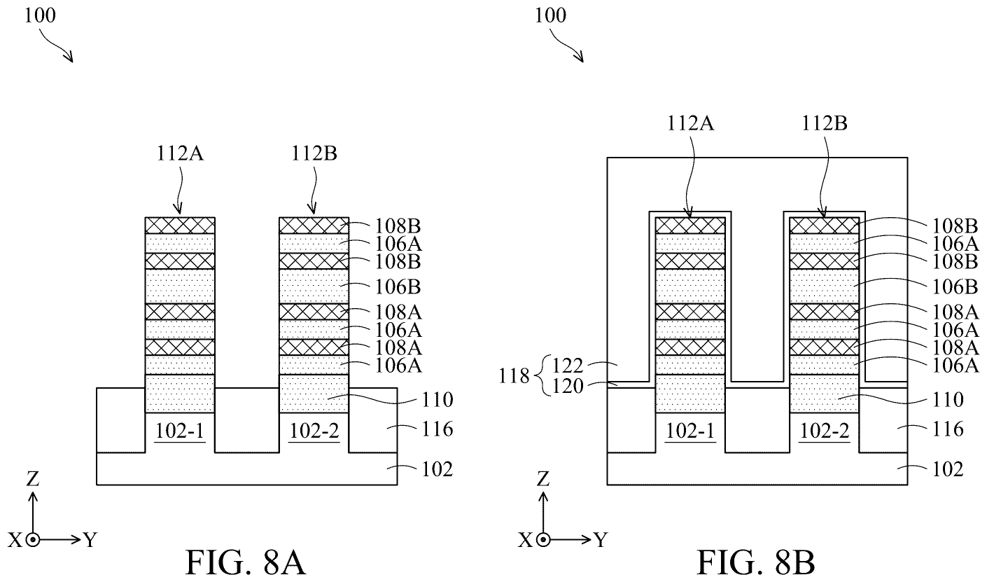

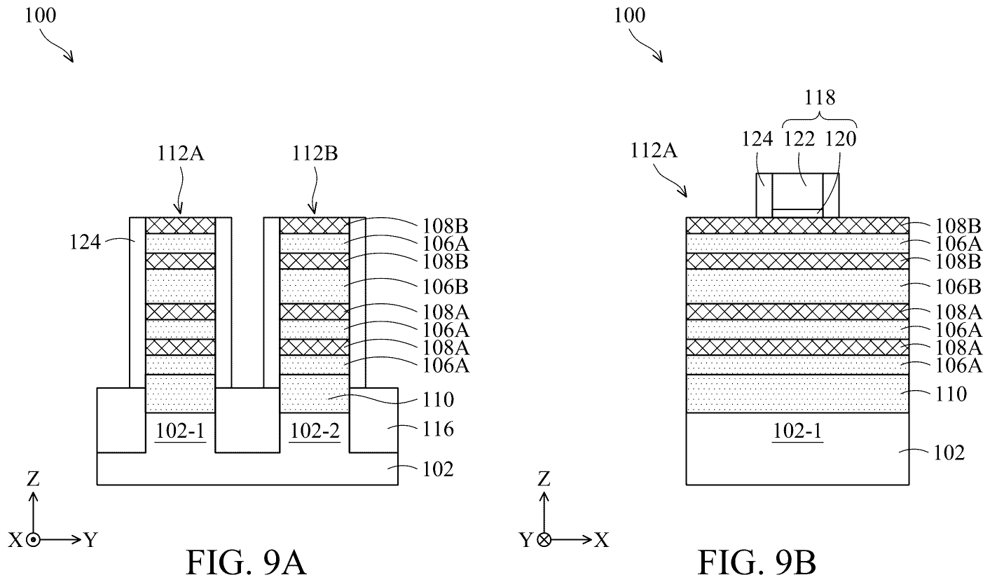

FIG. 8 is a perspective view of a workpiece 100 at a fabrication stage, in accordance with some embodiments of the present disclosure. FIGS. 6, 7, 8B, 21B, 22B, 23B, and 24B are Y-Z cross-sectional views of the workpiece 100 at various fabrication stages along a line A-A′ of FIG. 5, in accordance with some embodiments of the present disclosure. FIGS. 8A, 9A, 10A, 11A, 12A, 13A, 14A, 15A, 16A, 17A, 18A, 19A, 20A, and 25B are Y-Z cross-sectional views of the workpiece 100 at various fabrication stages along a line B-B′ of FIG. 5, in accordance with some embodiments of the present disclosure. FIGS. 9B, 10B, 11B, 12B, 13B, 14B, 15B, 16B, 17B, 18B, 19B, 20B, 21A, 22A, 23A, 24A, and 25A are X-Z cross-sectional views of the workpiece 100 at various fabrication stages along a line C-C′ of FIG. 5, in accordance with some embodiments of the present disclosure.

Referring to FIG. 5, the workpiece 100 is provided. The workpiece 100 may include a substrate 102 and a stack 204 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include one or more doped regions or well regions, such as n-type well regions doped with an n-type dopant (i.e., phosphorus (P), arsenic (As), other n-type dopant, or combinations thereof) or p-type well regions doped with a p-type dopant (i.e., boron (B), indium (In), other p-type dopant, or combinations thereof), for forming different types of devices or transistors. The doping the n-type wells and the p-type wells may be formed using ion implantation or thermal diffusion. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 (including semiconductor layers 106A and a semiconductor layer 106B), semiconductor layers 108 (including semiconductor layers 108A and 108B), and a semiconductor layer 110, and the semiconductor layers 106 and 108 are alternately stacked in the Z-direction. As shown in FIG. 5, a thickness of the semiconductor layer 106B is greater than a thickness of the semiconductor layers 106A. In some embodiments, the semiconductor layer 106B is formed vertically between a group of the semiconductor layers 108A and a group of the semiconductor layers 108B. Furthermore, the semiconductor layer 110 is formed under the alternately stacked semiconductor layers 106 and 108, as shown in FIG. 5. In some embodiments, a thickness of the semiconductor layer 110 is in a range from about 3 nm to about 15 nm.

The semiconductor layers 106, 108, and 110 may have different semiconductor compositions. In some embodiments, the semiconductor layers 106 and 110 are formed of silicon germanium (SiGe) and the semiconductor layers 108 are formed of silicon (Si). In these embodiments, the additional germanium content in the semiconductor layers 106 and 110 allow selective removal or recess of the semiconductor layers 106 and 110 without substantial damages to the semiconductor layers 108, so that the semiconductor layers 106 and 110 are also referred to as sacrificial layers. Furthermore, the semiconductor layers 106 and 110 have different germanium content. More specifically, the semiconductor layers 106 each has about 10% to about 15% of germanium, and the semiconductor layer 110 has about 10% to about 15% of germanium. Therefore, the selective etching or recessing can be performed to etch the semiconductor layer 110 without substantial damages to the semiconductor layers 106.

In some embodiments, the semiconductor layers 106, 108, and 110 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layer 110 is first deposited, and then the semiconductor layers 106 and the semiconductor layers 108 are deposited alternatingly, one-after-another, to form the stack 104.

The two (2) semiconductor layers 108A are used for each of PFETs of CFETs and the two (2) semiconductor layers 108B are used for NFETs of the CFETs. It should be noted that four (4) layers of the semiconductor layers 106 and four (4) layers of the semiconductor layers 108 are alternately and vertically arranged (or stacked) as shown in FIG. 5, which are for illustrative purposes only and not intended to be limiting beyond what is specifically recited in the claims. The number of the layers depends on the desired number of channels members for the semiconductor device.

Referring to FIG. 6, the substrate 102 and the stack 104 are then patterned to form fins 112A and 112B (may be collectively referred to as fins 112) over the substrate 102. For patterning purposes, the workpiece 100 may also include a hard mask layer 114 over the stack 104 before the patterning of the substrate 102 and the stack 104. The hard mask layer 114 may be a single layer or a multi-layer. In some embodiments, the hard mask layer 114 is a single layer and includes a silicon germanium layer. In some embodiments, the hard mask layer 114 is a multi-layer and includes a silicon nitride layer and a silicon oxide layer over the silicon nitride layer. In some other embodiments, the hard mask layer 114 is a multi-layer and includes a silicon germanium layer and a silicon layer over the silicon germanium layer.

As shown in FIG. 6, each of the fins 112 includes a base fin (i.e., the base portions 102-1 and 102-2 of the substrate 102) formed from the substrate 102 and a stack portion formed from the stack 104 over the base portion. In some aspects, the base fins 102-1 and 102-2 protrude from the substrate 102. Each of the fins 112 may include the semiconductor layer 110, and the semiconductor layers 106 and 108 alternating stacked in the Z-direction. The fins 112 extend lengthwise (e.g., longitudinally) in the X-direction (shown in FIG. 9B), extend vertically in the Z-direction over the substrate 102, and are arranged in the Y-direction, as shown in FIG. 6. In some embodiments, widths of the fins 112 in the Y-direction are the same. Although two fins 112 are formed and shown herein, less or more fins may be formed, such as three or more fins.

The fins 112 may be patterned using suitable processes including double-patterning or multi-patterning processes. For example, in some embodiments, a material layer of the hard mask layer 114 is formed over the substrate 102 and patterned into the hard mask layer 114 using a photolithography process. One or more etching processes are then performed to etch the stack 104 and top portions of the substrate 102 not covered by the hard mask layer 114 to form the fins 112. The etching process may include dry etching, wet etching, reactive ion etching (RIE), and/or other suitable processes.

Referring to FIG. 7, isolation feature (or isolation structure) 116 is formed. More specifically, after the fins 112 are formed, the isolation feature 116 are formed over the substrate 102. In some embodiments, the isolation feature 116 extends in the X-direction (not shown) and is arranged with the fins 212 in the Y-direction. In some aspects, the isolation structures 116 are formed between the fins 112. In some other aspects, the isolation feature 116 is formed around the fins 212. Furthermore, the isolation feature 116 is also formed between the base portions 102-1 and 102-2 of the substrate 102, as shown in FIG. 7. More specifically, the isolation structures 116 are formed between and around the base fins (e.g., 102-1 and 102-2) of the fins 112. In other aspects, the isolation features 116 are formed on opposite sides of the fins 112 (semiconductor layers 106, 108, and 110) in the Y-direction.

The isolation feature 116 may include different structures, such as shallow trench isolation (STI) structures and/or deep trench isolation (DTI) structures. In some embodiments, the isolation feature 116 may also be referred to as shallow trench isolation (STI) feature. In some embodiments, a dielectric material for the isolation feature 116 is first deposited over the workpiece 100. In some embodiments, the dielectric material may include silicon oxide, silicon nitride, silicon oxynitride, silicon carbide, borosilicate glass (BSG), phosphoric silicate glass (PSG), borophosphosilicate glass (BPSG), fluorine-doped silicate glass (FSG), a low-k dielectric (e.g., a carbon doped oxide, SiCOH), combinations thereof, and/or other suitable materials (for example, including silicon, oxygen, nitrogen, carbon, or other suitable isolation constituent). In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation feature 116.

In some embodiments, the isolation feature 116 may have a multi-layer structure such as a thermal oxide liner layer over the substrate 102 and a filling layer (e.g., silicon nitride or silicon oxide) over the thermal oxide liner layer. In some embodiments, before the formation of the isolation feature 116, a liner layer may be conformally deposited over the substrate 102 using ALD or CVD. Furthermore, as shown in FIG. 7, bottom surfaces of the stack portions of the fins 112 are lower than top surfaces of the isolation feature 116 while the base portions 102-1 and 102-2 are surrounded by the isolation feature 116. In some embodiments, top surfaces (or topmost surfaces) of the substrate 102 are lower than the top surfaces of the isolation feature 116. In other words, the top surfaces of the isolation feature 116 are higher than the top surfaces (or the topmost surfaces) of the substrate 102.

Referring to FIGS. 8A and 8B, the mask layer 110 is removed and a dummy gate structure 118 is formed over the fins 112 and over the isolation feature 116. The dummy gate structure 118 may be configured to extend along the Y-direction and wrap around top surfaces and side surfaces of the fins 112, as shown in FIG. 8B. In some embodiments, to form the dummy gate structure 118, a dummy interfacial material of a dummy interfacial layer 120 is first formed over fins 112 and over the isolation feature 116.

In some embodiments, the dummy interfacial layer 120 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 122 is formed over the dummy interfacial material. The dummy gate material may include a conductive material selected from a group comprising polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

After the formation of the dummy gate material and the dummy interfacial material, lithography and etching processes may be performed to remove portions of the dummy gate material and the dummy interfacial material, thereby forming the dummy gate structure 118 with dummy gate electrode 122 and the dummy interfacial layer 120. The dummy gate structure 118 may undergo a gate replacement process through subsequent processing to form metal gates, such as a high-k metal gate, as discussed in greater detail below.

Referring to FIGS. 9A and 9B, after the formation of the dummy gate structure 118, the gate spacers 124 are formed on sidewalls of the dummy gate structure 118, over the top surfaces of the fins 112, and on the sidewalls of the fins 112. More specifically, the gate spacers 124 are formed on opposite the sidewalls of the fins 112, as shown in FIG. 9A, and formed on opposite the sidewalls of the dummy gate structures 118, as shown in FIG. 9B. The gate spacers 124 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. The gate spacers 124 may include a single layer or a multi-layer structure.

In some embodiments, the gate spacers 124 may be formed by conformally depositing a spacer layer (containing the dielectric material) over the isolation feature 116, the fins 112, and the dummy gate structure 118, followed by an anisotropic etching process to remove top portions of the spacer layer from the top surfaces of the isolation feature 116, the fins 112, and the dummy gate structure 118. After the etching process, portions of the spacer layer on the sidewall surfaces of the fins 112 and the dummy gate structure 118 substantially remain and become the gate spacers 124. In some embodiments, the anisotropic etching process is a dry (e.g., plasma) etching process. Additionally or alternatively, the formation of the gate spacers 124 may also involve chemical oxidation, thermal oxidation, ALD, CVD, and/or other suitable methods. The gate spacers 124 may also be interchangeably referred to as gate top spacers or top spacers.

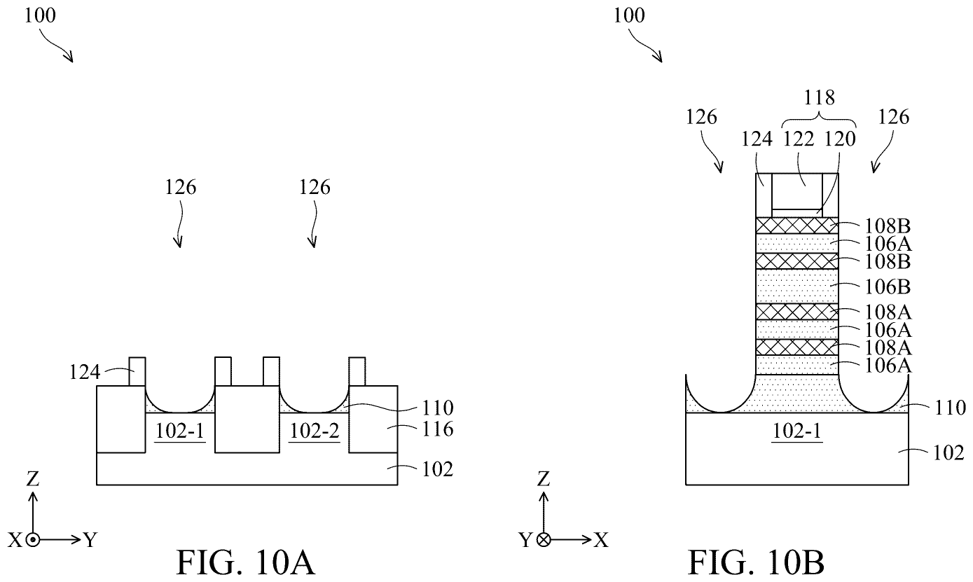

Referring to FIGS. 10A and 10B, portions of the fins 112 are recessed to form source/drain trenches 126 in the fins 112 (or passing through the semiconductor layers 106, 108, and 110). Specifically, the source/drain trenches 126 may be formed by performing one or more etching processes to remove portions of the semiconductor layers 106, the semiconductor layers 108, and the semiconductor layer 110 that do not vertically overlap or be covered by the dummy gate structure 118 and the gate spacers 124. In some embodiments, a single etchant may be used to remove the semiconductor layers 106, the semiconductor layers 108, and the semiconductor layer 110, whereas in other embodiments, multiple etchants may be used to perform the etching process. In some embodiments, portions of the gate spacers 124 on the opposite sidewalls of the fins 112 are removed, as shown in FIG. 10A. The thickness of the gate spacers 124 on the opposite sidewalls of the fins 112 are reduced.

After the formation of the source/drain trenches 126 in the fins 112, sidewalls of the semiconductor layers 106, the semiconductor layers 108, and the semiconductor layer 110 are exposed in the source/drain trenches 126 in the X-direction, as shown in FIG. 10B. Furthermore, the source/drain trenches 126 exactly touch/reach the top surfaces of the substrate 102, as shown in FIGS. 10A and 10B. In some embodiments, portions of the substrate 102 is removed/recessed during the formation of the source/drain trenches 126.

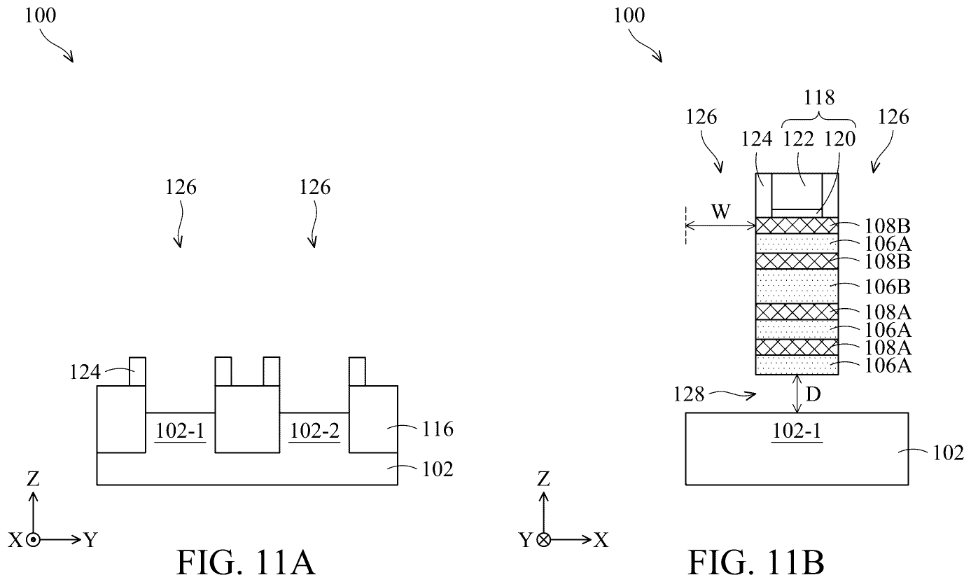

Referring to FIGS. 11A and 11B, the semiconductor layer 110 is removed through the source/drain trenches 126. The semiconductor layer 110 is removed by a selective etching process. More specifically, the selective etching process is performed that selectively etches the semiconductor layers 110 through the source/drain trenches 126, with minimal (or no) etching of the semiconductor layers 106, the semiconductor layers 108, the gate spacers 124, the isolation feature 116, and the substrate 102, such that gaps 128 are formed between the fins 112 (more specifically, the (bottommost) semiconductors 106A) and the substrate 102 in the Z-direction, below the gate spacers 124 and the dummy gate structures 118. The etching process is configured to laterally etch (e.g., along the X-direction) the semiconductor layer 110 below the gate spacers 124 and the dummy gate structures 118. The selective etching process is a dry etching process, a wet etching process, other suitable etching process, or combinations thereof.

As discussed above, the thickness of the semiconductor layer 110 is in the range from about 3 nm to about 15 nm. Therefore, in some embodiments, a dimension D of the gaps 128 in the Z-direction is also in a range from about 3 nm to about 15 nm, as shown in FIG. 11B. Furthermore, a width W of the source/drain trenches 126 in the X-direction is greater than the dimension D of the gaps 128 in the Z-direction, as shown in FIG. 11B.

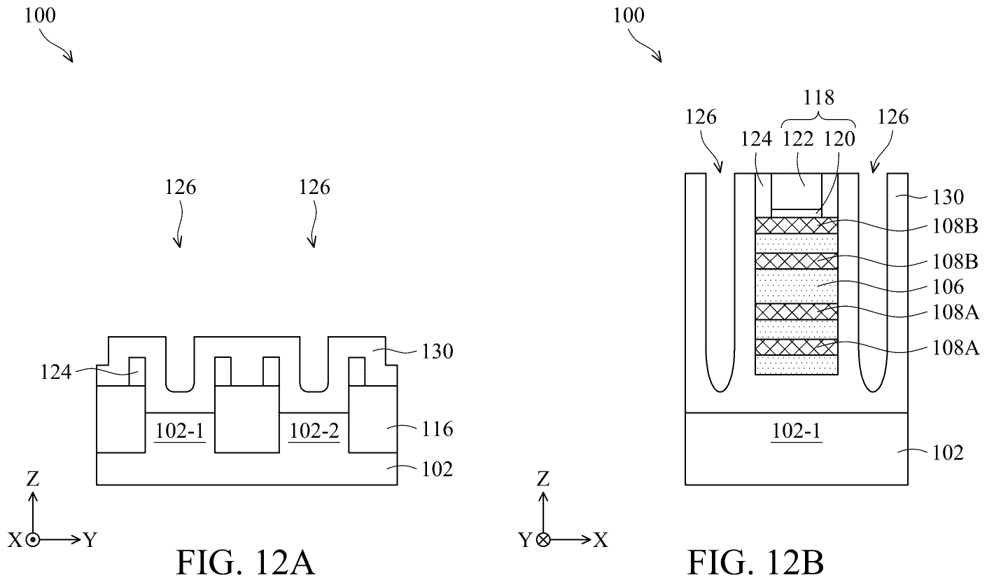

Referring to FIGS. 12A and 12B, a dielectric material 130 is conformally formed into the source/drain trenches 126 and the gaps 128. In some embodiments, a deposition process is performed to form the dielectric material 130 into the source/drain trenches 126 and the gaps 128, such as CVD, PVD, ALD, HDPCVD, MOCVD, RPCVD, PECVD, LPCVD, ALCVD, APCVD, other suitable methods, or combinations thereof. The dielectric material 130 partially fills the source/drain trenches 126 and fully fills the gaps 128, as shown in FIGS. 12A and 12B. More specifically, as shown in FIG. 12B, the dielectric material 130 is conformally formed on the top surfaces of the substrate 102 (exposed in the source/drain trenches 126) and on sidewalls of the gate spacers 124, the semiconductor layers 106, and the semiconductor layers 108. Furthermore, the dielectric material 130 is also conformally formed on bottom surfaces of the (bottommost) semiconductor layers 106 exposed in the gaps 128.

The deposition process is configured to ensure that the dielectric material 130 fully fills the gaps 128 between the (bottommost) semiconductor layers 106 and the substrate 102 direct under the gate spacers 124 and the dummy gate structures 118. As discussed above, the dimension D of the gaps 128 in the Z-direction is in a range from about 3 nm to about 15 nm (due to the thickness of the semiconductor layer 110 is in the range from about 3 nm to about 15 nm), as shown in FIG. 11B. If the dimension D of the gaps 128 is too small (less than about 3 nm), the dielectric material 130 is hard to fill into the gaps 128. If the dimension D of the gaps 128 is too large (greater than about 15 nm), the dielectric material 130 is hard to fully fill the gaps 128 (there may be some holes/caves in the dielectric material 130 in the gaps 128).

Furthermore, as discussed above, the width W of the source/drain trenches 126 in the X-direction is greater than the dimension D of the gaps 128 in the Z-direction, as shown in FIG. 11B. If the width W of the source/drain trenches 126 in the X-direction is less than the dimension D of the gaps 128 in the Z-direction, the source/drain trenches 126 may be blocked by the dielectric material 130 before fully filling the gaps 128 (i.e., the dielectric material 130 seals the top openings of the source/drain trenches 126).

The dielectric material 130 includes a material that is different than materials of the semiconductor layers 106 and 108, and a material of the gate spacers 124, to achieve the desired etching selectivity during the etching process. In some embodiments, the dielectric material 130 includes a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)).

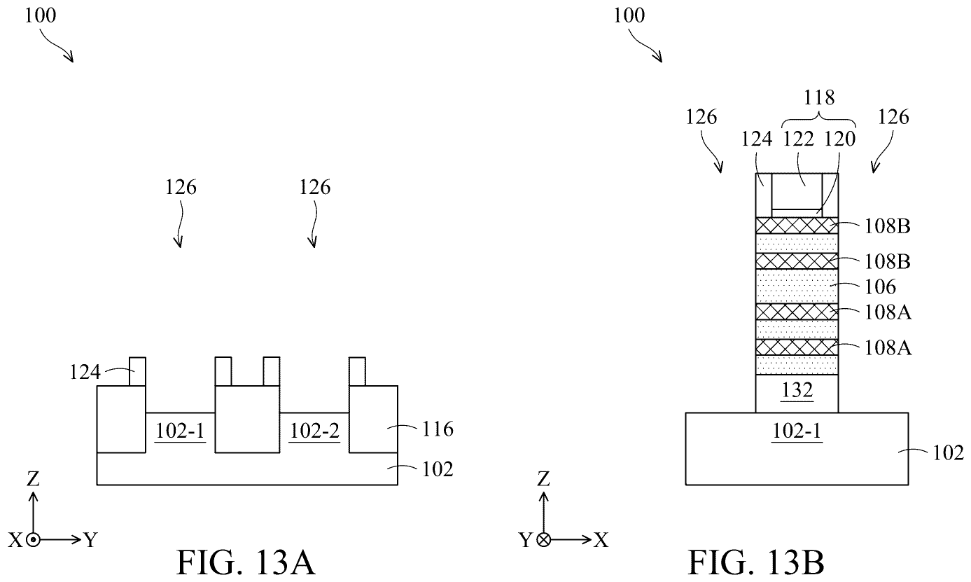

Referring to FIGS. 13A and 13B, one or more etching processes are performed to trim the dielectric material 130 to partially remove the dielectric material 130 to form dielectric layers 132. More specifically, one or more etching processes are performed to remove the dielectric material 130 exposed in the source/drain trenches 126 and the dielectric material 130 in the gaps 128 remain to form the dielectric layers 132. Therefore, the dielectric layers 132 are made of the dielectric material 132 and include Si₃N₄, SiO₂, SiC, SiOC, SiON, SiCN, SiOCN, or a combination thereof.

The one or more etching processes are selective etching processes that are performed to selectively etch the dielectric material 130 exposed in the source/drain trenches 126 through the source/drain trenches 126, with minimal (or no) etching of the dummy gate structures 118, the semiconductor layers 106 and 108, the gate spacers 124, the isolation features 116, and the substrate 102.

The etching process may be an anisotropic etching process, such that the etching process is configured to vertically etch (e.g., along the Z-direction) the dielectric material 130 that do not vertically overlap or be covered by the dummy gate structure 118 and the gate spacers 124. The selective etching process is a dry etching process, a wet etching process, other suitable etching process, or combinations thereof. As such, the dielectric material 130 is trimmed into the dielectric layers 132 between the (bottommost) semiconductor layers 106 and the substrate 102 direct under the dummy gate structures 118 and the gate spacers 124, as shown in FIG. 13B. Therefore, the semiconductor layer 110 discussed above are replaced with the dielectric layers 132.

As discussed above, the dimension D of the gaps 128 in the Z-direction is in a range from about 3 nm to about 15 nm (due to the thickness of the semiconductor layer 110 is in the range from about 3 nm to about 15 nm). Therefore, in some embodiments, a thickness of the dielectric layers 132 in the Z-direction is also in a range from about 3 nm to about 15 nm, as shown in FIG. 13B. If the thickness of the dielectric layers 132 is too small (less than about 3 nm), it is hard to form the dielectric layers 132 due to the dielectric material 130 is hard to fill into the gaps 128, as discussed above. If the thickness of the dielectric layers 132 is too large (greater than about 15 nm), the dielectric layers 132 may be formed with holes/caves due to the dielectric material 130 is hard to fully fill the gaps 128 (there may be some holes/caves in the dielectric material 130 in the gaps 128).

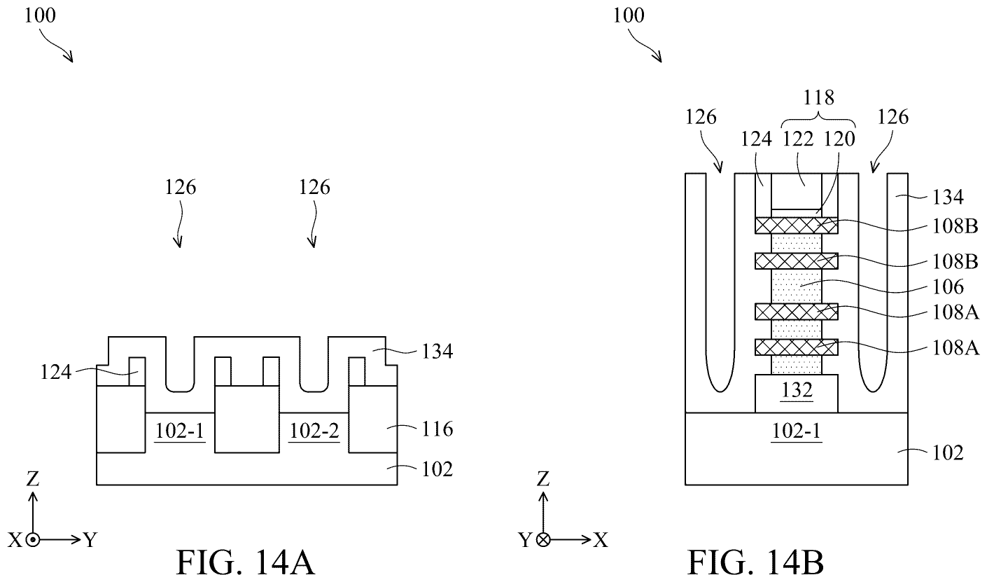

Referring to FIGS. 14A and 14B, side portions of the semiconductor layers 106 (including the semiconductor layers 106A and 106B) are removed via a selective etching process, and the semiconductor layers 108 are not removed. Specifically, the selective etching process is performed that selectively etches the side portions of the semiconductor layers 106 below the gate spacers 124 through the source/drain trenches 126, with minimal (or no) etching of the semiconductor layers 108, such that gaps are vertically formed between the semiconductor layers 108 as well as between the semiconductor layers 108 and the dielectric layers 132, below the gate spacers 124. The etching process is configured to laterally etch (e.g., along the X-direction) the semiconductor layers 106 below the gate spacers 124. The selective etching process is a dry etching process, a wet etching process, other suitable etching process, or combinations thereof.

Still referring to FIGS. 14A and 14B, a spacer layer 134 is conformally formed into the source/drain trenches 126 and the gaps between the semiconductor layers 108 as well as between the semiconductor layers 108 and the dielectric layer 132. More specifically, a deposition process is performed to form the spacer layer 134 into the source/drain trenches 126 and the gaps between the semiconductor layers 108 as well as between the semiconductor layer 108 and the dielectric layer 132, such as CVD, PVD, ALD, HDPCVD, MOCVD, RPCVD, PECVD, LPCVD, ALCVD, APCVD, other suitable methods, or combinations thereof. The spacer layer 134 partially (and, in some embodiments, completely) fills the source/drain trenches 126 and fully fills the gaps between the semiconductor layers 108 as well as between the semiconductor layers 108 and the dielectric layers 132, as shown in FIG. 14B. The deposition process is configured to ensure that the spacer layer 134 fills the gaps between the semiconductor layers 108 as well as between the semiconductor layer 108 and the dielectric layer 132 under the gate spacers 124. Furthermore, the spacer layer 134 is also conformally formed on the gate spacers 124, the isolation feature 116, and the substrate 102, as shown in FIG. 14A.

The spacer layer 134 includes a material that is different than a material of the semiconductor layers 108, the material of the gate spacers 124, and the material of the dielectric layers 132, to achieve the desired etching selectivity during the etching process. In some embodiments, the spacer layer 134 include a dielectric material that includes silicon, oxygen, carbon, nitrogen, other suitable material, or combinations thereof (for example, silicon oxide (SiO₂), silicon oxynitride (SiON), silicon oxycarbide (SiOC), silicon carbon nitride (SiCN), silicon oxycarbon nitride (SiOCN)). In some embodiments, the spacer layer 134 includes a low-k dielectric material, such as those described herein.

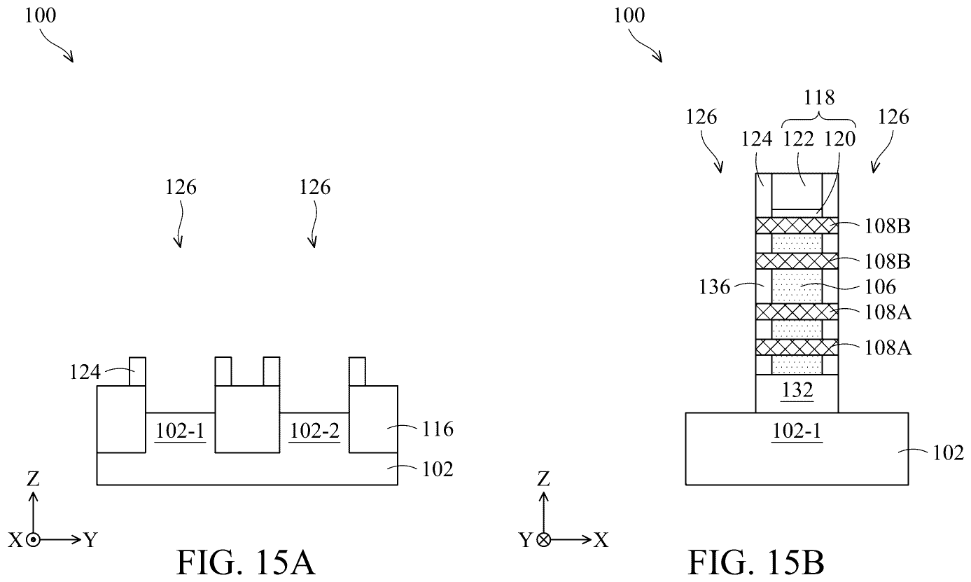

Referring to FIGS. 15A and 15B, the inner spacers 136 are formed to fill the gaps between the semiconductor layers 108 as well as between the semiconductor layer 108 and the dielectric layer 132. More specifically, an etching process is then performed that selectively etches the spacer layer 134 to form the inner spacers 136 with minimal (to no) etching of the semiconductor layers 108, the dielectric layers 132, the substrate 102, the dummy gate structures 118, and the gate spacers 124. The etching process may be an anisotropic etching process, such that the spacer layer 134 that do not vertically overlap or be covered by the dummy gate structure 118 and the gate spacers 124 are removed. The spacer layer 134 on the gate spacers 124 and the isolation feature 116 are removed, as shown in FIG. 15A. In some embodiments, sidewalls of the inner spacers 136 are aligned to the sidewalls of the gate spacers 124, the semiconductor layers 108, and the dielectric layer 132, as shown in FIG. 15B. Therefore, the inner spacers 136 are formed on opposite sides of the dummy gate structure 118. Furthermore, the inner spacers 136 are also in contact with and vertically between the semiconductor layers 108 as well as between the semiconductor layer 108 and the dielectric layer 132, in accordance with some embodiments. It should be noted that the inner spacers 136 are separated from the substrate 102, as shown in FIG. 15B.

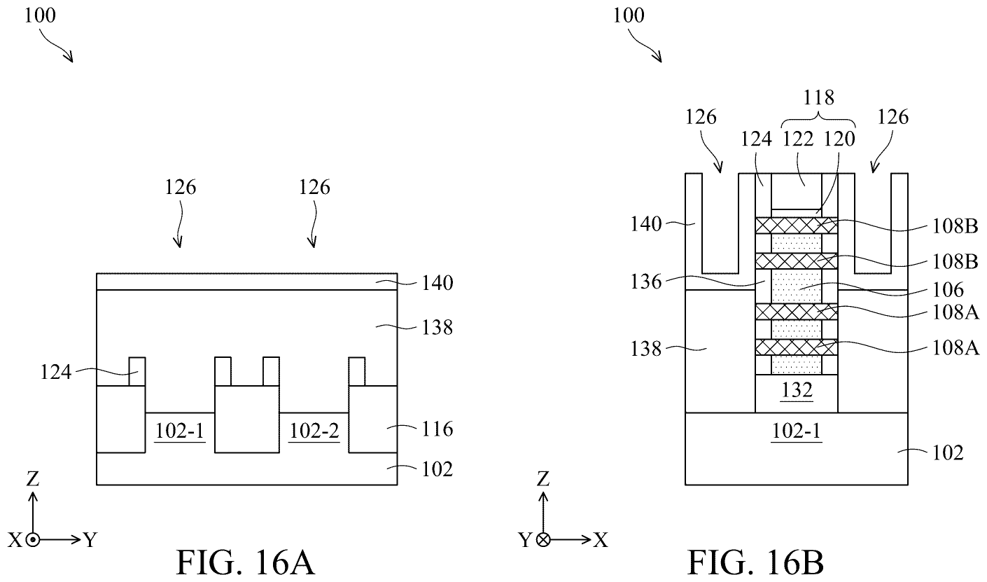

Referring to FIGS. 16A and 16B, polymer layers 138 and dielectric layers 140 are formed in the source/drain trenches 126. More specifically, the polymer layers 138 are first formed in lower parts of the source/drain trenches 126 to cover the top surfaces of the substrate 102, sidewalls of the dielectric layers 132, the sidewalls of the semiconductor layers 108A (which are used for the PFET of the CFET) and the inner spacers 136 (which are between the semiconductor layers 108A) exposed in the source/drain trenches 126. In some embodiments, top surfaces of the polymer layers 138 are lower than the semiconductor layers 108B. Furthermore, the polymer layers 138 is also formed on the gate spacers 124 and the isolation feature 116, as shown in FIG. 16A.

After the formation of the polymer layers 138, the dielectric layers 140 are conformally formed over the polymer layers 138 and on the sidewalls of the semiconductor layers 108B (which are used for the NFET of the CFET), the gate spacers 124, and the inner spacers 136 (which are between the semiconductor layers 108B). The polymer layers 138 are formed of fluorine-containing polymer and its molecular structure includes silicon (Si), carbon (C), nitrogen (N), or fluorine (F). In one example, the polymer layers 138 include fluorinated silicone or fluorinated polysilane. In some embodiments, the polymer layers 138 are spin-on-carbon layers. The polymer layers 138 may be deposited using CVD, flowable CVD (FCVD), or spin-on coating. The dielectric layers 140 may include aluminum oxide (Al₂O₃).

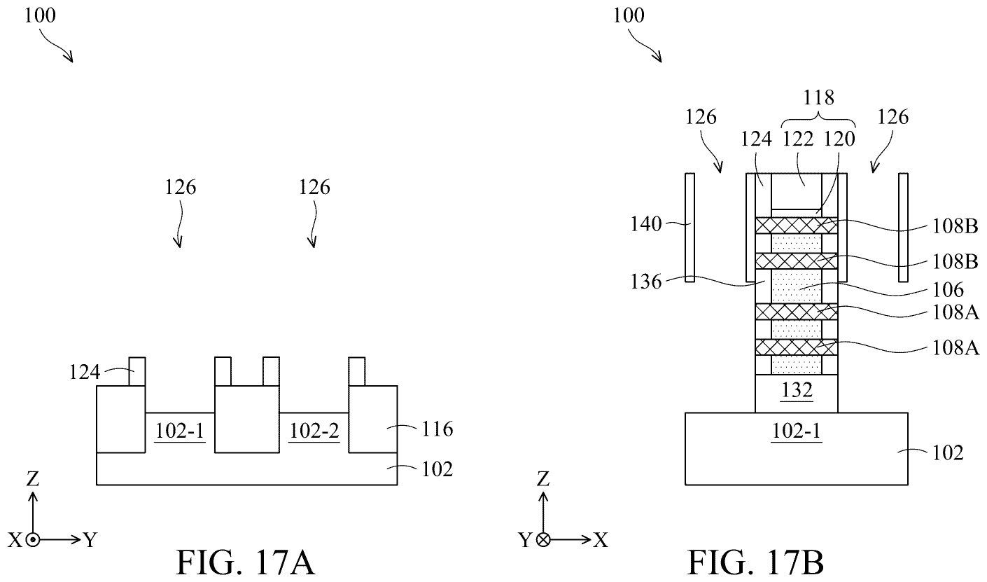

Referring to FIGS. 17A and 17B, horizontal portions of the dielectric layers 140 and the polymer layers 138 are removed. More specifically, an anisotropic etching process is performed to remove the horizontal portions of the dielectric layers 140 to exposed top surfaces of the polymer layers 138, and then a selective etching process is performed to remove the polymer layers 138. In some embodiments, portions of vertical portions of the dielectric layers 140 are removed or trimmed, but the remaining vertical portions of the dielectric layers 140 still cover the sidewalls of the gate spacers 124 and the semiconductor layers 108B, as shown in FIG. 17B. The selective etching process is performed that selectively etches the polymer layers 138 below the dielectric layers 140 through the source/drain trenches 126, with minimal (or no) etching of the semiconductor layers 108A, the dielectric layers 132, the substrate 102, the isolation feature 116, and the inner spacers 136. The selective etching process is a dry etching process, a wet etching process, other suitable etching process, or combinations thereof.

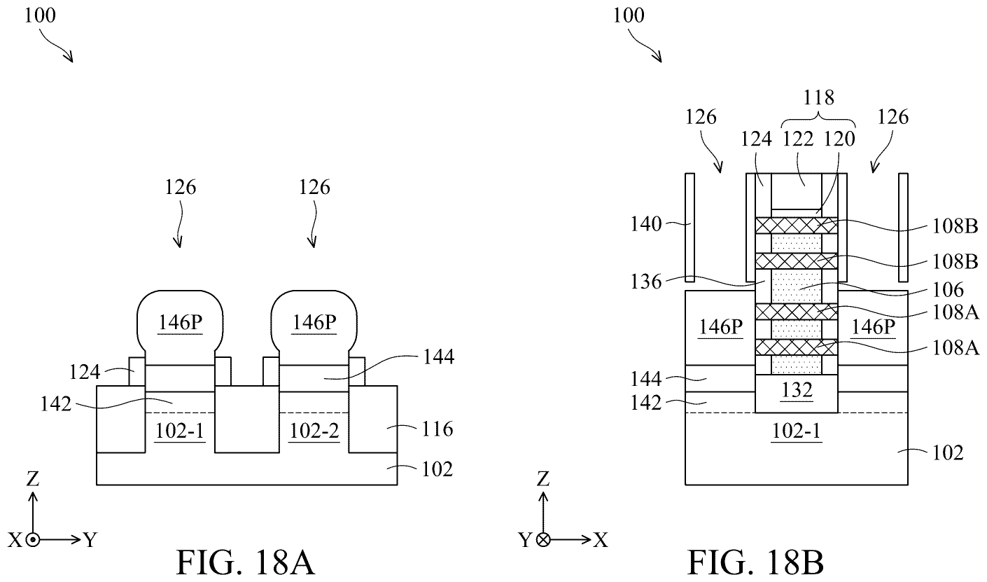

Referring to FIGS. 18A and 18B, after the removal of the polymer layers 1002, silicon layers 142 are formed in the lower parts of the source/drain trenches 126 and below the dielectric layers 140. More specifically, the silicon layers 142 are formed over the substrate 102 in the source/drain trenches 126. As shown in FIGS. 18A and 18B, the silicon layers 142 are also formed on opposite sides of the dummy gate structures 118, the semiconductor layers 106, the semiconductor layers 108, and the dielectric layers 132. In some embodiments, the silicon layers 142 are in contact with the sidewalls of the dielectric layers 132 in the X-direction, as shown in FIG. 18B. Furthermore, the silicon layers 142 are also in contact with the sidewalls of the isolation feature 116 in the Y-direction, as shown in FIG. 18A. In some embodiment, top surfaces of the silicon layers 142 are lower than top surfaces of the dielectric layers 132 and the bottommost surfaces of the semiconductor layers 106 (more specifically, the bottommost semiconductor layer 106), in the X-Z cross-sectional view, as shown in FIG. 18B. In some embodiment, the silicon layers 142 each has a planar bottom surface, as shown in FIGS. 18A and 18B.

The silicon layers 142 are made of silicon without dopants. In other word, the silicon layers 142 are un-doped silicon, and thus may be referred to as un-doped silicon layers. As such, the leakage current of the resultant transistors from one source/drain feature to another source/drain feature through the substrate 102 is prevented, thereby improving performances of the resultant transistors. One or more epitaxy processes may be performed to form the silicon layers 142. Epitaxy processes may implement CVD deposition techniques (for example, vapor-phase epitaxy (VPE), UHVCVD, LPCVD, and/or PECVD), molecular beam epitaxy, other suitable SEG processes, or combinations thereof.

Still referring to FIGS. 18A and 18B, after the formation of the silicon layers 142, the bottom dielectric layers 144 and the source/drain features 146P are formed in the lower parts of the source/drain trenches 126 and below the dielectric layers 140. More specifically, the bottom dielectric layers 144 are formed over the silicon layers 142 exposed in the source/drain trenches 126, and the source/drain features 146P are formed over the bottom dielectric layers 144. The bottom dielectric layers 144 are over the silicon layers 142 and under the source/drain features 146P. In other words, the bottom dielectric layers 144 are vertically between and in contact with the source/drain features 146P and the silicon layers 142 in the Z-direction, as shown in FIGS. 18A and 18B.

As shown in FIGS. 18A and 18B, the bottom dielectric layers 144 are also formed on opposite sides of the dummy gate structures 118, the semiconductor layers 106, the semiconductor layers 108, and the dielectric layers 132. In some embodiments, bottom dielectric layers 144 are in contact with the sidewalls of the dielectric layers 132 in the X-direction, as shown in FIG. 18B. Furthermore, the bottom dielectric layers 144 are also in contact with the sidewalls of the isolation feature 116 and the gate spacers 124 in the Y-direction, as shown in FIG. 18A. The top surfaces of the bottom dielectric layers 144 are higher than the top surfaces of the dielectric layers 132, such that the bottom dielectric layers 144 separate the source/drain features 146P from the dielectric layers 132, as shown in FIG. 18B.

As shown in FIG. 18B, the source/drain features 146P are also formed on opposite sides of the dummy gate structure 118 in the X-direction. Furthermore, the source/drain features 146P are disposed on opposite sides of the semiconductor layers 108A in the X-direction, as shown in FIG. 18B. More specifically, the source/drain features 146P are connected to and in contact with the semiconductor layers 108A. Therefore, the source/drain features 146P are attached and electrically connected to the semiconductor layers 108A in the X-direction. In some aspects, the semiconductor layers 108A extend in the X-direction to connect one source/drain feature 146P to another source/drain feature 146P.

In some embodiments, the source/drain features 146P may have top surfaces that extend higher than top surfaces of the topmost semiconductor layers 108A (e.g., in the Z-direction). In other embodiments, the top surfaces of the source/drain features 146P substantially level with the top surfaces of the topmost semiconductor layers 108A. Furthermore, the top surfaces of the source/drain features 146P are lower than the bottom surfaces of the semiconductor layers 108B, as shown in FIG. 18B. In some embodiments, bottom surfaces of the source/drain features 146P are lower than bottom surfaces of the bottommost semiconductor layers 108A. In other embodiments, the bottom surfaces of the source/drain features 146P are substantially level with the bottom surfaces of the bottommost semiconductor layers 108A.

One or more epitaxy processes may be employed to grow the source/drain features 146P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 146P are grown from the semiconductor layers 108A rather than the substrate 102 and the semiconductor layers 108B due to the bottom dielectric layers 144 cover the silicon layers 142 and the substrate 102 and the dielectric layers 140 cover the sidewalls of the semiconductor layers 108B.

The source/drain features 146P may include any suitable semiconductor materials. For example, the source/drain features 146P used for the PFETs of the CFETs may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 146P may be doped with P-type dopants (such as boron, indium, other P-type dopant, or a combination thereof) having a doping concentration in a range from about 1×10¹⁹/cm³ to 6×10²⁰/cm³.

The source/drain features 146P may also be referred to as source/drain, or source/drain regions. In some embodiments, source/drain feature(s) 146P may refer to a source or a drain, individually or collectively dependent upon the context. In some embodiments, the source/drain features 146P may be referred to as P-type source/drain features. The source/drain features 146P may be doped in-situ or ex-situ. One or more annealing processes may be performed to activate the dopants in the source/drain features 146P. The annealing processes may include rapid thermal annealing (RTA) and/or laser annealing processes.

In some embodiments, the dielectric material of the bottom dielectric layers 144 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the silicon layers 142 and the bottom dielectric layers 144 are under the source/drain features 146P. Therefore, the source/drain features 146P are separated and electrically isolated from the substrate 102 by the silicon layers 142 and the bottom dielectric layers 144. As such, it prevents the leakage current of the resultant semiconductor device (more specifically, the CFETs) from one source/drain feature 146P to another source/drain feature 146P through the substrate 102, thereby improving performances of the resultant semiconductor device.

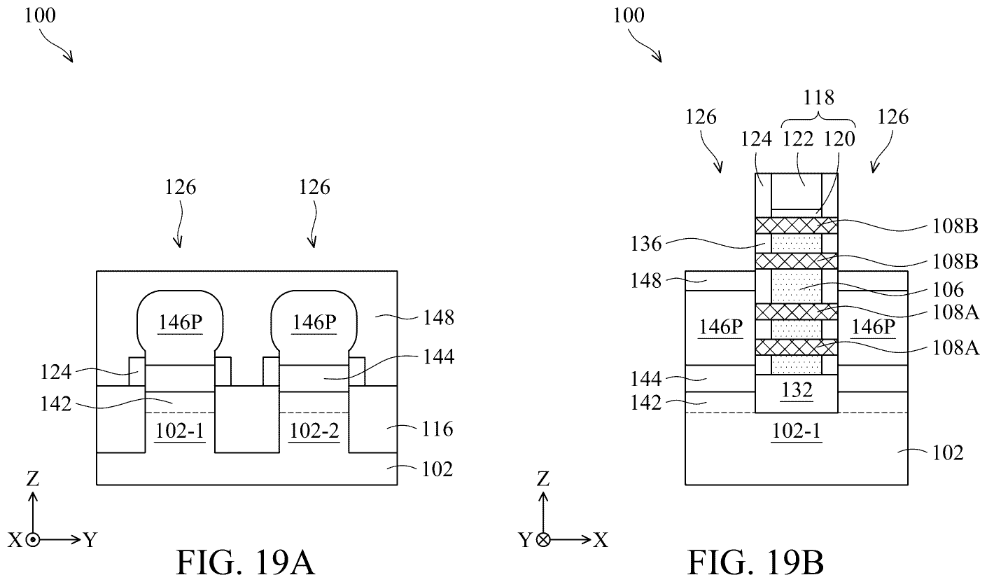

Referring to FIGS. 19A and 19B, the dielectric layers 140 are removed via a selective etching process, and then an interlayer dielectric (ILD) layer 148 over the substrate 102, the isolation feature 116, and the source/drain features 146P are formed in the source/drain trenches 126. Specifically, the selective etching process is performed that selectively etches the dielectric layers 140 over the source/drain features 146P through the source/drain trenches 126, with minimal (or no) etching of the semiconductor layers 108B, the gate spacers 124, and the inner spacers 136. The selective etching process is a dry etching process, a wet etching process, other suitable etching process, or combinations thereof.

After the removal of the dielectric layers 140, the ILD layer 148 is then formed over the substrate 102, the isolation feature 116, and the source/drain features 148P and between the spaces between the source/drain features 148P, as shown in FIGS. 19A and 19B. Then, the ILD layer 148 over the source/drain features 148P are recessed by performing one or more lithography and etching processes, so that the sidewalls of the semiconductor layers 108B over the source/drain features 148P are exposed.

The ILD layer 148 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 148 may be formed by PECVD (plasma enhanced CVD), FCVD (flowable CVD), or other suitable methods.

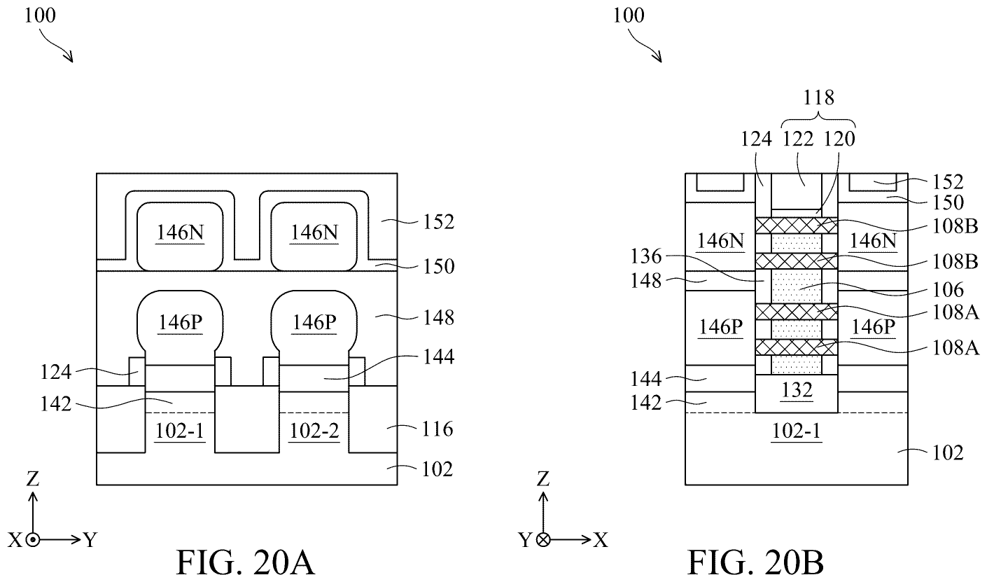

Referring to FIGS. 20A and 20B, the source/drain features 146N are formed in the source/drain trenches 126. Specifically, the source/drain features 146N are formed over the ILD layer 148 in the source/drain trenches 126. The source/drain features 146N are also disposed on opposite sides of the dummy gate structure 214 in the X-direction, as shown in FIG. 20B. The source/drain features 146N are connected to and in contact with the semiconductor layers 108B. Therefore, the source/drain features 146N are attached and electrically connected to the semiconductor layers 108B in the X-direction. In some aspects, the semiconductor layers 108B extend in the X-direction to connect one source/drain feature 146N to another source/drain feature 146N.

In some embodiments, the source/drain features 146N may have top surfaces that extend higher than top surfaces of the topmost semiconductor layers 108B (e.g., in the Z-direction). In other embodiments, the top surfaces of the source/drain features 146N are substantially level with the top surfaces of the topmost semiconductor layers 108B. In some embodiments, the bottom surfaces of the source/drain features 146N are lower than bottom surfaces of the bottommost semiconductor layers 108B. In other embodiments, the bottom surfaces of the source/drain features 146N are substantially level with the bottom surfaces of the bottommost semiconductor layers 108B.

One or more epitaxy processes may be employed to grow the source/drain features 146N. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 146N are grown from the semiconductor layers 108B.

The source/drain features 146N may include any suitable semiconductor materials. For example, the source/drain features 146N used for the NFETs of the CFETs may include epitaxially-grown material selected from a group consisting of SiP, SiC, SiPC, SiAs, Si, or a combination thereof. In some embodiments, the epitaxially-grown material of the source/drain features 146N may be doped with N-type dopants (such as phosphorus, arsenic, other N-type dopant, or a combination thereof) having a doping concentration in a range from about 2×10¹⁹/cm³ to 3×10²¹/cm³.

The source/drain features 146N may also be referred to as source/drain, or source/drain regions. In some embodiments, source/drain feature(s) 146N may refer to a source or a drain, individually or collectively dependent upon the context. In some embodiments, the source/drain features 146N may be referred to as N-type source/drain features. The source/drain features 146N may be doped in-situ or ex-situ. One or more annealing processes may be performed to activate the dopants in the source/drain features 146N. The annealing processes may include rapid thermal annealing (RTA) and/or laser annealing processes.

Furthermore, the ILD layer 148 is vertically between an in contact with the source/drain features 146P and the source/drain features 146N in the Z-direction, as shown in FIGS. 20A and 20B. As such, the source/drain features 146P is separated and electrically isolated from the source/drain features 146N by the ILD layer 148. As discussed above, the width W of the source/drain trenches 126 in the X-direction is greater than the dimension D of the gaps 128 in the Z-direction, as shown in FIG. 11B. Therefore, as shown in FIG. 20B, a width of the source/drain features 146P and 146N in the X-direction is greater than the thickness of the dielectric layers 132 in the Z-direction.

Still referring to FIGS. 20A and 20B, contact etch stop layers (CESLs) 150 over the source/drain features 146N and the ILD layer 148 and an interlayer dielectric (ILD) layer 152 over the CESLs 150 are formed to fill the space between the source/drain features 146N. Specifically, the CESLs 150 are conformally formed on the sidewalls of the gate spacers 124. In some embodiments, the CESLs 150 are also conformally formed on the top surfaces and the sidewalls of the source/drain features 146N, as shown in FIG. 20A. The ILD layer 152 is formed over and between the CESLs 150 to fill the space in the CESLs 150 and between the gate spacers 124 and in the source/drain trenches 126. After the formation of the CESLs 150 and the ILD layer 152, a CMP process is performed to reduce heights of the CESLs 150 and the ILD layer 152 until top surfaces of the dummy gate electrode 122 of the dummy gate structure 118 are exposed.

The CESLs 150 include a material that is different than ILD layer 152. The CESLs 150 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 152 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 152 may be formed by PECVD (plasma enhanced CVD), FCVD (flowable CVD), or other suitable methods.

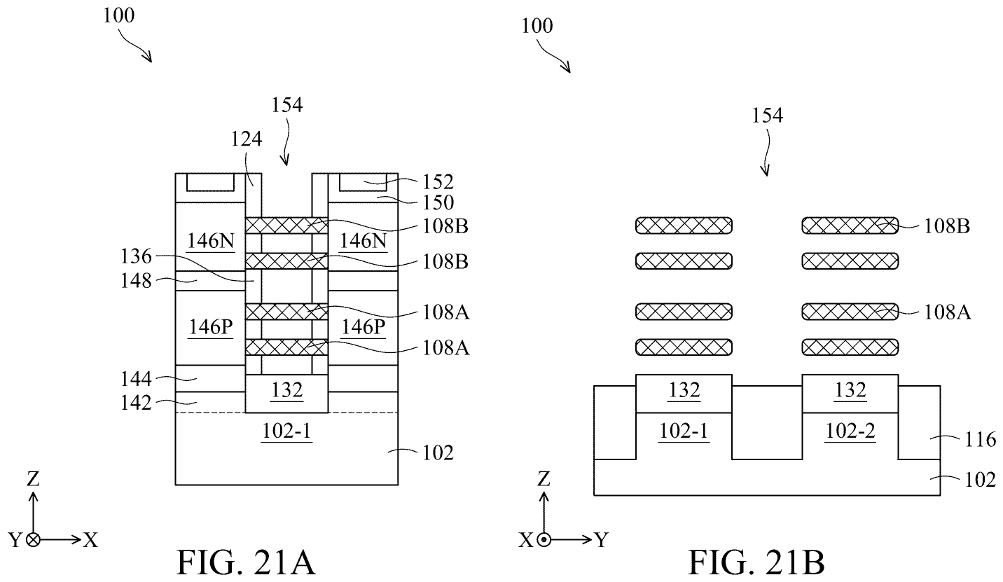

Referring to FIGS. 21A and 21B, the dummy gate structure 118 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structure 118. Then, the dummy gate structure 118 are selectively etched through the masking element. The gate spacers 124 may be used as the masking element or a part thereof. Etch selectivity may be achieved by selecting the appropriate etching chemicals, and the dummy gate structure 118 may be removed without substantially affecting the CESLs 150 and the ILD layer 152. The removal of the dummy gate structure 118 creates a gate trench 154. The gate trench 154 exposes the top surfaces of the topmost semiconductor layers 108A that underlies the dummy gate structure 118.

Still referring to FIGS. 21A and 21B, the semiconductor layers 106 of the fins 112 are selectively removed through the gate trench 154, using a wet or dry etching process for example, so that the semiconductor layers 108A and 108B are exposed in the gate trench 154 to form nanostructures stacked over each other. As such, the semiconductor layers 108 may be referred to as nanostructures. The semiconductor layers 108A and 108B may be referred to as the nanostructures 108A and 108B as the context requires. Specifically, the semiconductor layers 108A (the nanostructures 108A) are stacked vertically in the Z-direction, and the semiconductor layers 108B (the nanostructures 108B) are directly over the semiconductor layers 108A and are stacked vertically in the Z-direction. Such a process may also be referred to as a wire release process, a nanowire release process, a nanosheet release process, a nanowire formation process, a nanosheet formation process, or a wire formation process.

In some embodiments, the removal of the semiconductor layers 106 causes the exposed semiconductor layers 108A or 108B to be spaced apart from each other in the vertical direction (e.g., in the Z-direction). The exposed semiconductor layers 108 extend longitudinally in the horizontal direction (e.g., in the X-direction). Furthermore, each of the semiconductor layers 108A connects one source/drain feature 146P to another source/drain feature 146P, and each of the semiconductor layers 108B connects one source/drain feature 146N to another source/drain feature 146N. In some embodiments, during the removal of the semiconductor layers 106, middle portions of the semiconductor layers 108A and 108B are partially removed to form the nanostructures 108A and 108B with the dumbbell-shapes in the X-Z cross-sectional view. In some embodiments, as shown in FIG. 21A, after the removal of the semiconductor layers 106, the dielectric layers 132 are exposed in the gate trench 154. Furthermore, sidewalls of the dielectric layers 132 are also partially exposed in the gate trench 154, as shown in FIG. 21B.

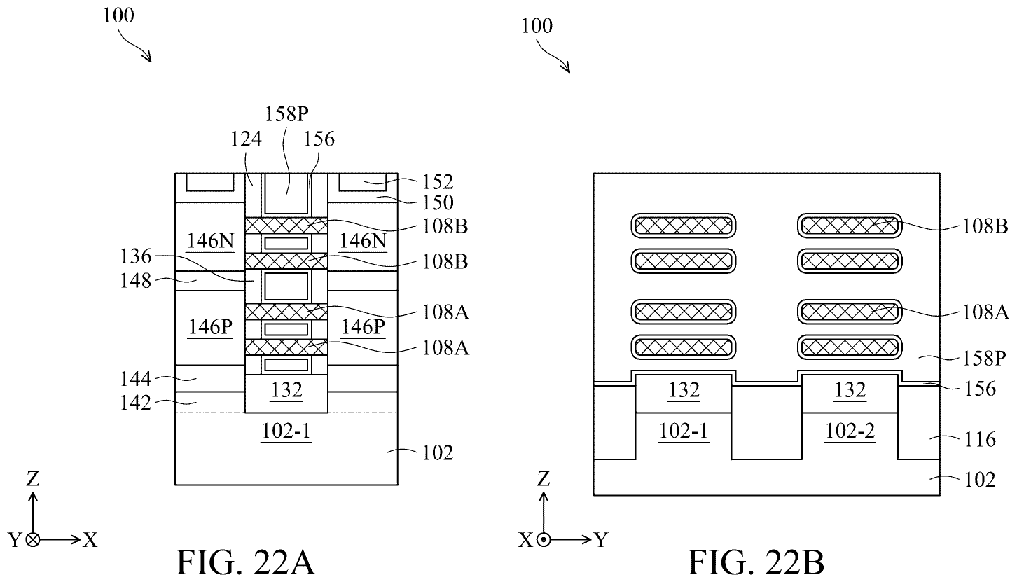

Referring to FIGS. 22A and 22B, a gate dielectric layer 156 and a gate electrode layer 158P are formed in the gate trench 154 to wrap around (the middle portions of) the semiconductor layers 108A and 108B (the nanostructures 108A and 108B). More specifically, the gate dielectric layer 156 wrap around each of the semiconductor layers 108A and 108B (the nanostructures 108A and 108B), and the gate electrode layer 158P wrap around the gate dielectric layer 156 and each of the semiconductor layers 108A and 108B (the nanostructures 108A and 108B). Additionally, the gate dielectric layer 156 is also formed on the sidewalls of the inner spacers 136 and the gate spacers 124 (shown in FIG. 22A), as well as over the top surfaces of the dielectric layers 132 and the isolation feature 116 (shown in FIG. 22B).

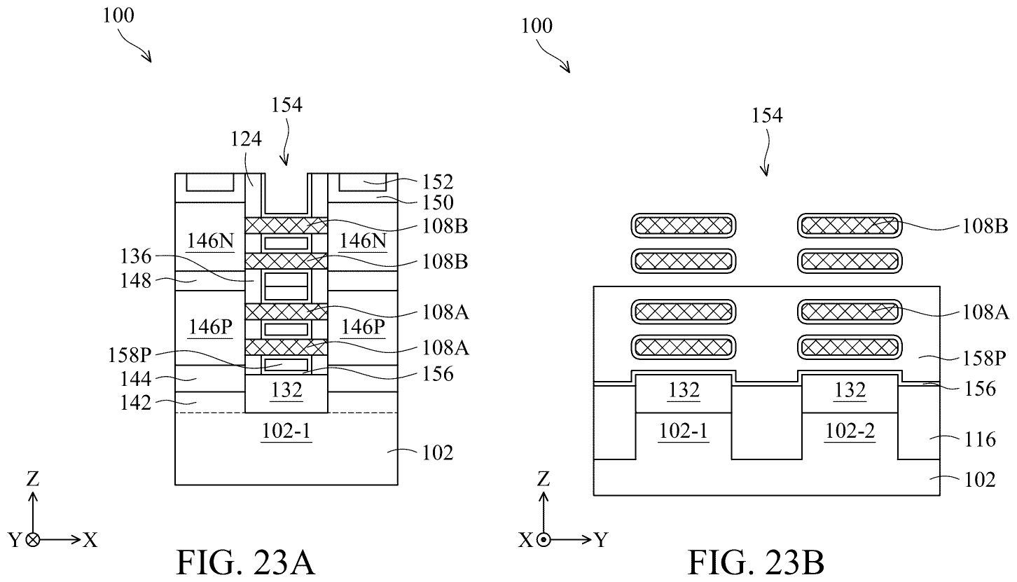

Referring to FIGS. 23A and 23B, the gate electrode layer 158P in the gate trench 154 are etched back to expose the gate dielectric layer 156 wrapping around (the middle portions of) the semiconductor layers 108B (the nanostructures 108B). More specifically, portions the gate electrode layer 158P wrapping around the semiconductor layers 108B (the nanostructures 108B) are removed by performing one or more etching processes. The etching processes may be selective etching processes that selectively etch the gate electrode layer 158P, with minimal (or no) etching of the gate dielectric layer 156, the semiconductor layers 108B (the nanostructures 108B), the gate spacers 124, and the inner spacers 136. The selective etching process is a dry etching process, a wet etching process, other suitable etching process, or combinations thereof. As shown in FIGS. 23A, after the etching processes, a top surface of the gate electrode layer 158P is lower than bottommost surfaces of the semiconductor layers 108B (the nanostructures 108B) and top surfaces of the ILD layer 148, in accordance with some embodiments.

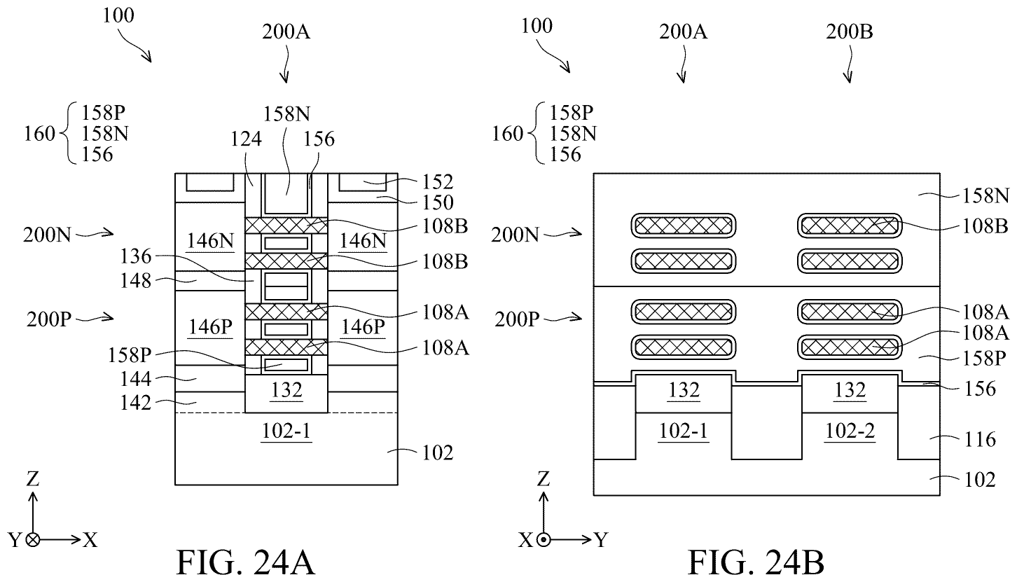

Referring to FIGS. 24A and 24B, a gate electrode layer 158N are formed in the gate trench 228 and over the gate dielectric layer 156 and the gate electrode layer 158P to wrap around the semiconductor layers 108B (the nanostructures 108B). More specifically, the gate electrode layer 158N wraps around the gate dielectric layer 156 wrapping around the semiconductor layers 108B (the nanostructures 108B) and each of the semiconductor layers 108B (the nanostructures 108B).

Therefore, the gate dielectric layer 156, the gate electrode layer 158P, and the gate electrode layer 158N may be together referred to as a gate structure 160 formed in the gate trench 154 to replace the dummy gate structure 118. In some aspects, the gate structure 160 wraps around the semiconductor layers 108A and 108B (the nanostructures 108A and 108B).

The gate dielectric layer 156 may include oxide with nitrogen doped dielectric material (initial layer) combined with metal content high-K dielectric material (K value (dielectric constant)>13). For example, the gate dielectric layer 156 may include hafnium oxide (HfO₂), which has a dielectric constant in a range from about 18 to about 40. Alternatively, the gate dielectric layer 156 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layer 156 may be formed by chemical oxidation, thermal oxidation, ALD, CVD, and/or other suitable methods.

In some embodiments, the gate electrode layer 158P may include one or more P-type work function metal layers for PFETs and the gate electrode layer 158N may include one or more N-type work function metal layers for NFETs. Therefore, the gate electrode layer 158P may be referred to as P-type work function metal layer 158P and the gate electrode layer 158N may be referred to as N-type work function metal layer 158N, as the context requires. In some embodiments, each of the gate electrode layers 158P and 158N may include a single layer or alternatively a multi-layer structure. The material of the N-type work function metal layer 158N and the P-type work function metal may layer 158P be the same. In some embodiments, the material of the N-type work function metal layer 158N and the P-type work function metal layer 158P are different.

In some embodiments, the N-type work function metal layer 158N include a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer 158N may be deposited utilizing ALD, CVD, or the like. However, any suitable materials and processes may be utilized to form the N-type work function metal layer 158N.

In some embodiments, the P-type work function metal layer 158P include a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer 158P may be deposited using a deposition process such as ALD, CVD, or the like, although any suitable deposition process may be used.

After the formation of the gate electrode layer 158N shown in FIGS. 24A and 24B, the workpiece 100 is formed into the semiconductor structure with CFETs 200A and 200B, in which each of the CFETs 200A and 200B includes a PFET 200P and a NFET 200N. In each of the CFETs 200A and 200B, the PFET 200P is over the substrate 102, and the NFET 200N is over the PFET 200P. As shown in FIGS. 24A and 24B, each of the PFET 200P is constructed by the semiconductor layers (nanostructures) 108A, the gate structure 160, and the source/drain features 146P, and each of the NFET 200N is constructed by the semiconductor layers (nanostructures) 108B, the gate structure 160, and the source/drain features 146N. The NFET 200N is disposed over the PFET 200P. As discussed above, the gate structure 160 wraps around the semiconductor layers 108A and 108B (the nanostructures 108A and 108B). As such, the NFET 200N and the PFET 200P in each of the CFETs share the same gate structure 160.

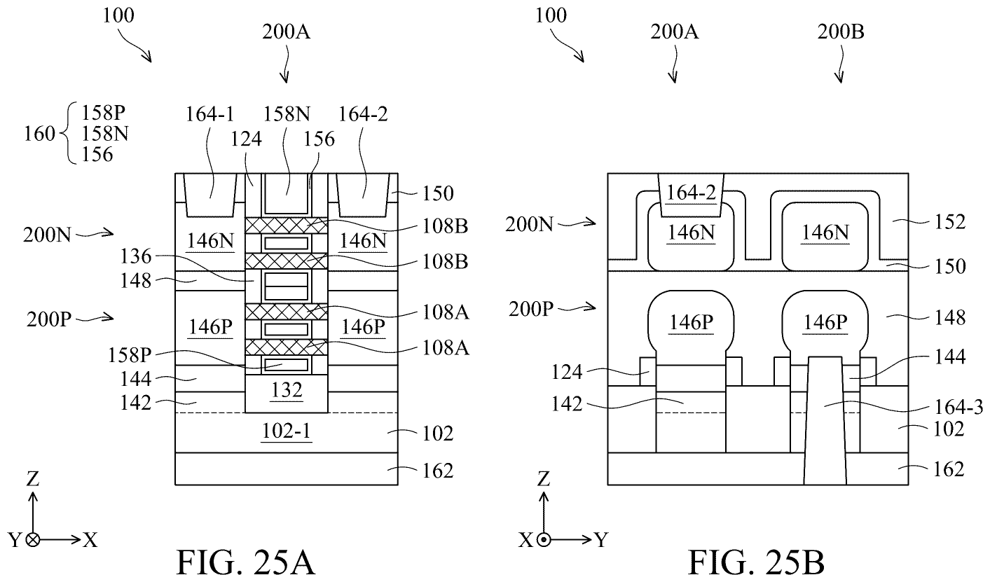

Referring to FIGS. 25A and 25B, after the formation of the gate electrode layer 158N, source/drain contacts 130-1 and 130-2 are formed to pass through the ILD layer 152, the CESLs 150, and portions of the source/drain features 146N to be in contact with and electrically connected to the source/drain features 146N, as shown in FIGS. 25A and 25B. Furthermore, a dielectric layer 162 is formed under the substrate 102, and then a source/drain contact 130-3 is formed to pass through the dielectric layer 162, the substrate 102, and a portion of the source/drain feature 146P to be in contact with and electrically connected to the source/drain feature 146P, as shown in FIGS. 25A and 25B.

The dielectric layer 162 includes a dielectric material nitride, such as Si₃N₄, SiO₂, SiC, SiOC, SiON, SiCN, SiOCN, carbon doped oxide, nitrogen doped oxide, porous oxide, or combinations thereof. The source/drain contacts 130-1, 130-2, and 130-3 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 130-1, 130-2, and 130-3 may each include single conductive material layer or multiple conductive layers.

As shown in FIGS. 25A and 25B, the dielectric layers 132 are under the gate structure 160 (specifically, under the gate dielectric layer 156, the gate electrode layer (P-type word function metal layer) 158P, and the gate electrode layer (N-type word function metal layer) 158N). In some embodiments, the dielectric layers 132 are over the substrate 102 and over the gate structure 160. In other words, the dielectric layers 132 are vertically between the substrate 102 and the gate structure 160 in the Z-direction, as shown in FIGS. 25A and 25B. Furthermore, the dielectric layers 132 are in contact with the gate structure 160 (more specifically, the gate dielectric layer 156), as shown in FIGS. 25A and 25B. As such, the gate structure 160 is vertically separated from the substrate 102 by the dielectric layers 132 in the Z-direction. Due the gate structure 160 is vertically separated from the substrate 102 by the dielectric layers 132 in the Z-direction, the parasitic capacitance between the gate structure 160 and the substrate 102 are reduced, thereby improving the resultant CFETs 200A and 200B.

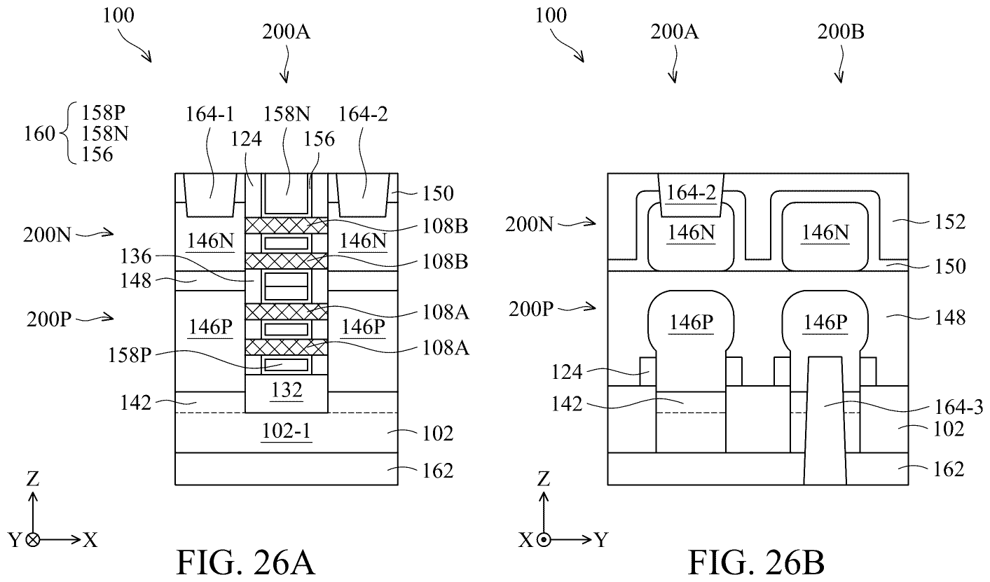

FIG. 26A is an X-Z cross-sectional view of the workpiece 100 at the fabrication stage shown in FIG. 25A, in accordance with some alternative embodiments of the present disclosure. FIG. 26B is a Y-Z cross-sectional view of the workpiece 100 at the fabrication stage shown in FIG. 25B, in accordance with some alternative embodiments of the present disclosure.

The workpiece 100 with CFETs 200A and 200B shown in FIGS. 26A and 26B are similar to the workpiece 100 with CFETs 200A and 200B shown in FIGS. 25A and 25B, except that the bottom dielectric layers 144 are omitted. More specifically, the bottom dielectric layers 144 are optional. As shown in FIGS. 26A and 26B, the source/drain feature 146P are in contact with the silicon layers 142 in the Z-direction. Furthermore, the source/drain features 146P are in contact with (the sidewalls of) the dielectric layers 132 in the X-direction, as shown in FIG. 26A. In some embodiments, the bottom surfaces of the source/drain features 146P are lower than the top surfaces of the isolation feature 116, as shown in FIG. 26B. The CFETs 200A and 200B without the dielectric layers 132 shown in FIGS. 26A and 26B may have larger source/drain features 146P. Such larger source/drain features 146P may have better strain for improved hole mobility.

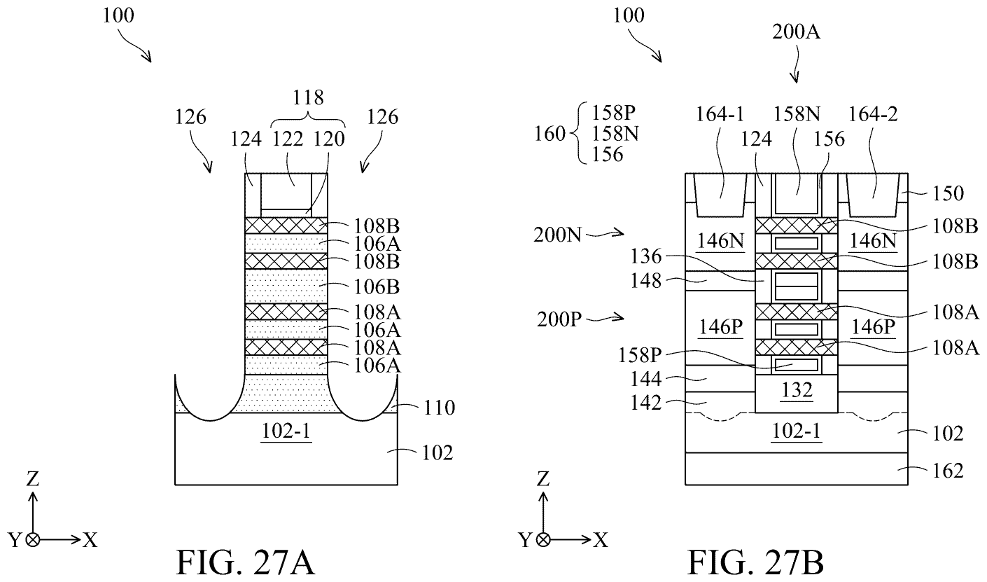

FIGS. 27A and 27B are X-Z cross-sectional views of the workpiece 100 at the fabrication stages shown in FIGS. 10B and 25A, in accordance with some alternative embodiments of the present disclosure. As discussed above, referring back to FIG. 10B, the source/drain trenches 126 exactly touch/reach the top surfaces of the substrate 102 after the recessing of the portions of the fins 112 for forming the source/drain trenches 126 in the fins 112. In some embodiments, portions of the substrate 102 are etched/removed/recessed during the recessing of the portions of the fins 112 for forming the source/drain trenches 126, as shown in FIG. 27A. As such, the substrate 102 have recesses, as shown in FIG. 27A. Referring to FIG. 27B, the sequent processes discussed above are performed on the workpiece 100 shown in FIG. 27A to form the CFETs 200A and 200B. The bottom surfaces of the silicon layers 142 are non-planar due to the recesses of the substrate 102 shown in FIG. 27A, as shown in FIG. 27B. Each of the silicon layers 142 has a rectangular shape with a convex protrusion protruded from the bottom surfaces of the silicon layers 142.

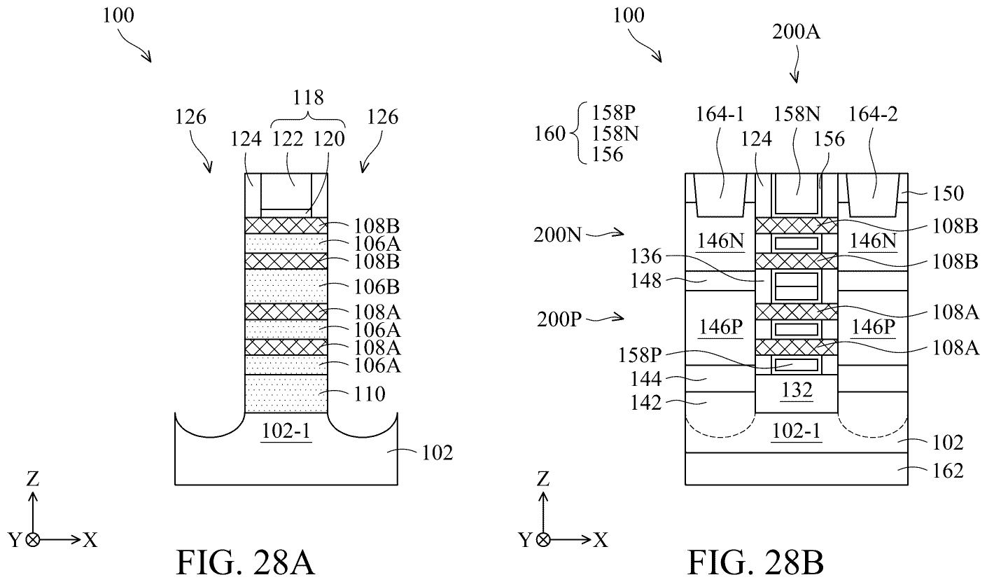

FIGS. 28A and 28B are X-Z cross-sectional views of the workpiece 100 at the fabrication stages shown in FIGS. 10B and 25A, in accordance with some alternative embodiments of the present disclosure. As discussed above, referring back to FIG. 10B, the source/drain trenches 126 exactly touch/reach the top surfaces of the substrate 102 after the recessing of the portions of the fins 112 for forming the source/drain trenches 126 in the fins 112. Similarly, in some embodiments, portions of the substrate 102 are etched/removed/recessed during the recessing of the portions of the fins 112 for forming the source/drain trenches 126, as shown in FIG. 28A. As such, the substrate 102 have recesses, as shown in FIG. 28A. Referring to FIG. 28B, the sequent processes discussed above are performed on the workpiece 100 shown in FIG. 28A to form the CFETs 200A and 200B. Similarly, the bottom surfaces of the silicon layers 142 are non-planar due to the recesses of the substrate 102 shown in FIG. 28A, as shown in FIG. 28B. Each of the silicon layers 142 has a convex bottom surfaces in contact with the substrate 102.

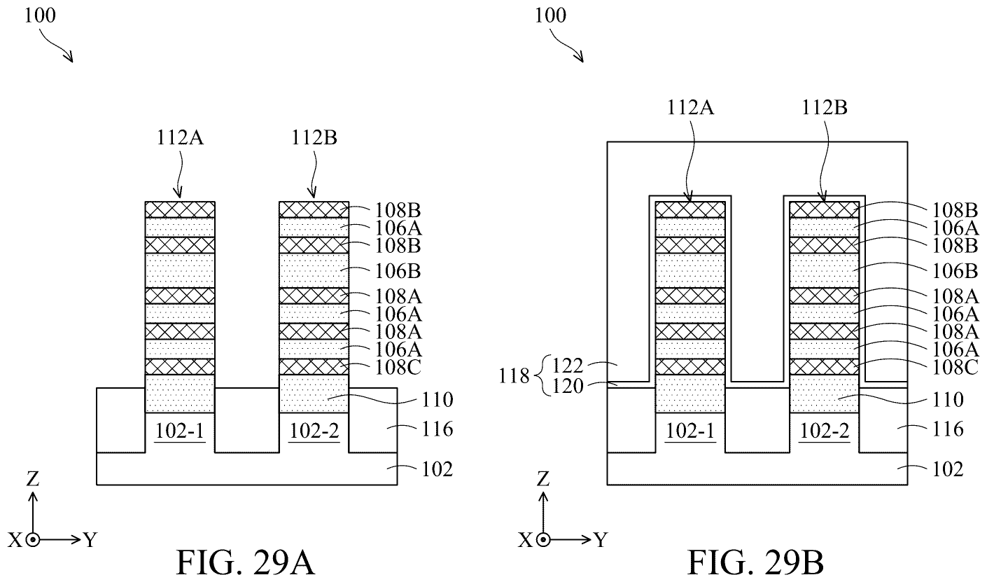

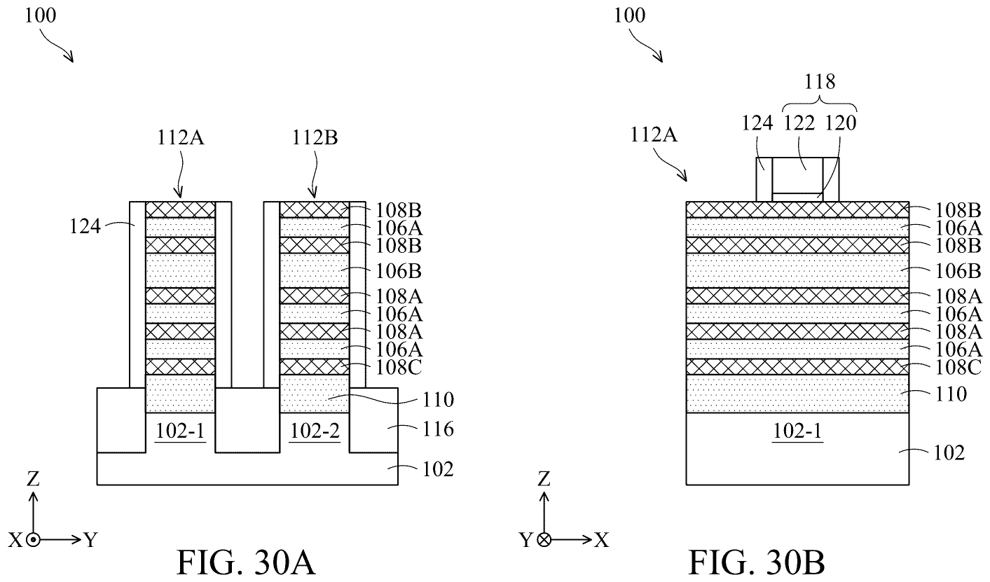

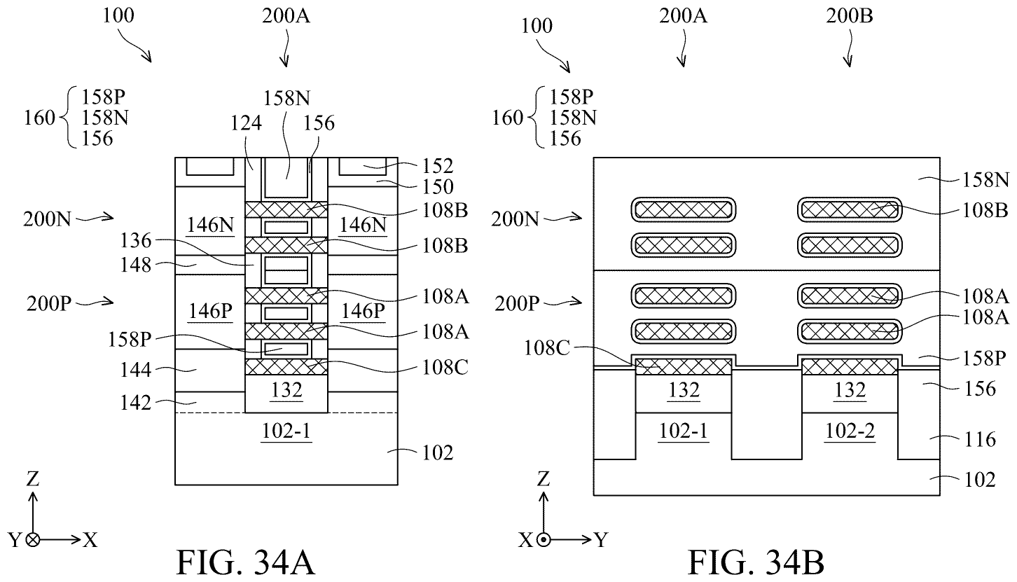

FIGS. 29B and 34B are Y-Z cross-sectional views of the workpiece 100 at a fabrication stage along the line A-A′ of FIG. 5, in accordance with some alternative embodiments of the present disclosure. FIGS. 29A, 30A, and 31A are Y-Z cross-sectional views of the workpiece 100 at various fabrication stages along the line B-B′ of FIG. 5, in accordance with some alternative embodiments of the present disclosure. FIGS. 30B, 31B, 32, 33, and 34A are X-Z cross-sectional views of the workpiece 100 at various fabrication stages along the line C-C′ of FIG. 5, in accordance with some alternative embodiments of the present disclosure.

Referring to FIGS. 29A and 29B, similar to FIGS. 8A and 8B, the dummy gate structure 118 discussed above is formed over the fins 112 and over the isolation feature 116. The difference between the workpiece 100 shown in FIGS. 8A and 8B and the workpiece 100 shown in FIGS. 29A and 29B is that the stack portions of the fins 112 discussed above further includes a semiconductor layer 108C. As shown in FIGS. 29A and 29B, the semiconductor layers 108C are formed under the semiconductors layers 106, 108A, and 108B. Furthermore, the semiconductor layers 108C are formed over the semiconductor layers 110. In other words, the semiconductor layers 108C are vertically between and in contact with the (bottommost) semiconductors layers 106 and the semiconductor layers 110 in the Z-direction, as shown in FIGS. 29A and 29B. The semiconductor layers 108C are similar to the semiconductor layers 108A and 1008B to be formed of silicon (Si). The semiconductor layers 108A, 108B, and 108C may be collectively referred to as the semiconductor layers 108. In some embodiments, the dummy interfacial layer 120 discussed above are formed on sidewalls of the semiconductor layers 108C, as shown in FIG. 29B.

Referring to FIGS. 30A and 30B, similar to FIGS. 9A and 9B, the gate spacers 124 discussed above are formed on sidewalls of the dummy gate structure 118, over the top surfaces of the fins 112, and on the sidewalls of the fins 112. As shown in FIG. 30A, the gate spacers 124 are formed on the sidewalls of the semiconductor layers 108C.

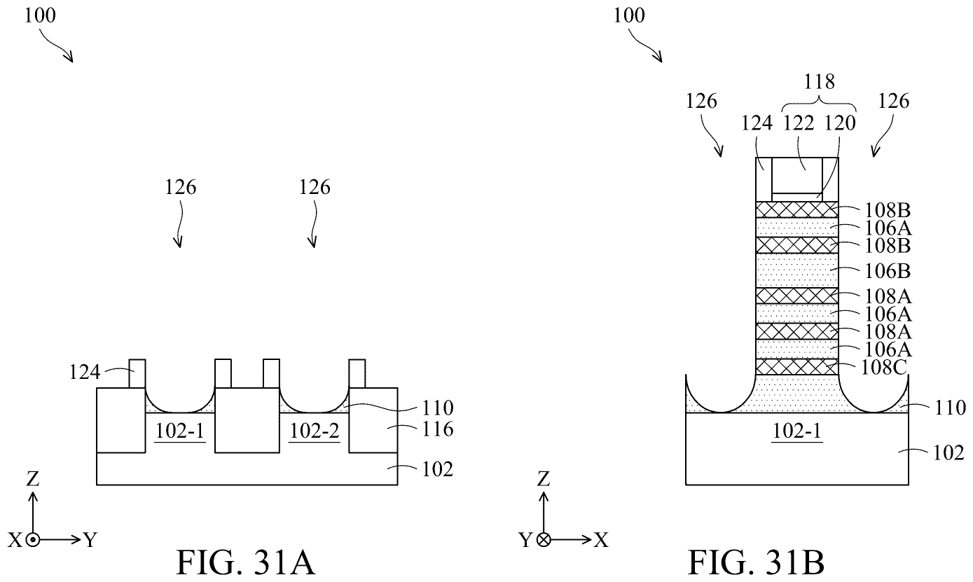

Referring to FIGS. 31A and 31B, similar to FIGS. 10A and 10B, the source/drain trenches 126 discussed above are formed in the fins 112. The source/drain trenches 126 are formed to remove portions of the semiconductor layers 106, the semiconductor layers 108 (including the semiconductor layers 108A, 108B, and 108C), and the semiconductor layer 110 that do not vertically overlap or be covered by the dummy gate structure 118 and the gate spacers 124. Therefore, the sidewalls of the semiconductor layers 106, the semiconductor layers 108 (including the semiconductor layers 108A, 108B, and 108C), and the semiconductor layer 110 are exposed in the source/drain trenches 126 in the X-direction, as shown in FIG. 31B.

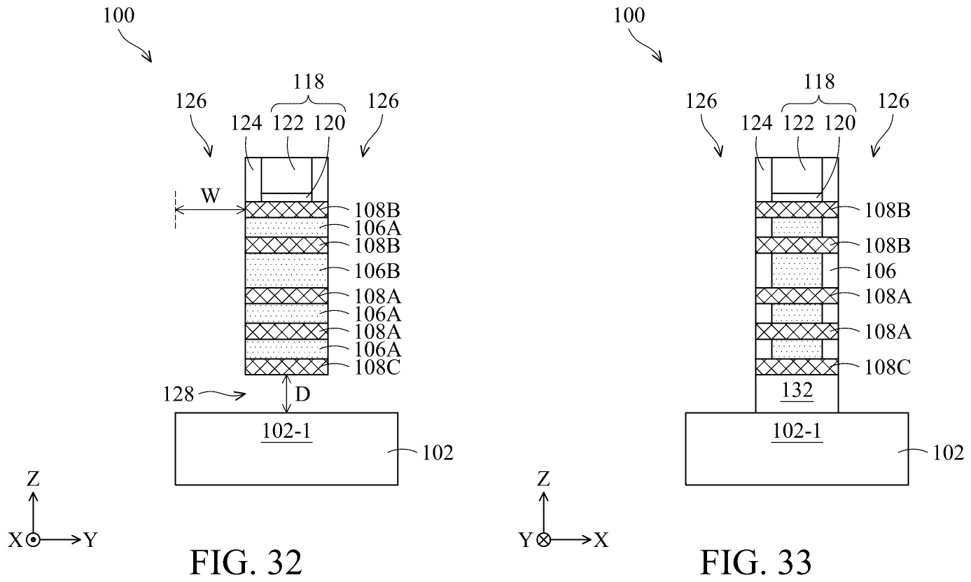

Referring to FIG. 32A, similar to FIG. 11B, the semiconductor layer 110 is removed through the source/drain trenches 126. Referring back to FIG. 10B, the semiconductor layer 110 is in contact with the (bottommost) semiconductor layer 106A in the Z-direction. As such, referring back to FIG. 11B, the bottom surface of the (bottommost) semiconductor layer 106A may has a risk to be etched/recessed/damaged during the removal of the semiconductor layer 110 although the semiconductor layer 106A and the semiconductor layer 110 have different germanium content for the selective etching (the semiconductor layers 106 each has about 10% to about 15% of germanium, and the semiconductor layer 110 has about 10% to about 15% of germanium, as discussed above). Such etching/recessing/damage of the (bottommost) semiconductor layer 106A may affect the reliability and/or the performance of the resultant CFETs.

As shown in FIG. 31B, the semiconductor layers 108C are vertically between and in contact with the (bottommost) semiconductors layers 106 and the semiconductor layers 110 in the Z-direction. Therefore, the bottom surface of the (bottommost) semiconductor layers 106A are protected and covered by the semiconductor layers 108C during the removal of the semiconductor layer 110. The selective etching process is performed that selectively etches the semiconductor layers 110 through the source/drain trenches 126, with minimal (or no) etching of the semiconductor layers 106, the semiconductor layers 108 (including the semiconductor layers 108A, 108B, and 108C), the gate spacers 124, the isolation feature 116, and the substrate 102, such that the gaps 128 are formed between the fins 112 (more specifically, the (bottommost) semiconductors 106A) and the substrate 102 in the Z-direction, below the gate spacers 124 and the dummy gate structures 118.

Even if the semiconductor layers 108C are etched/recessed/damaged during the removal of the semiconductor layer 110, since the semiconductor layers 108C are electrically nonfunctional in the resultant CFETs, the reliability and/or the performance of the resultant CFETs will not be affected. Furthermore, due to the semiconductor layers 108C are electrically nonfunctional, the semiconductor layers 110 can be removed by the selective etching process with higher etching rate without etching/recessing/damage of the (bottommost) semiconductor layer 106A. Therefore, such structure also has higher process window.

Referring to FIG. 33, similar to FIG. 13B, the dielectric layers 132 are formed. As shown in FIG. 33, the dielectric layers 132 are vertically between and in contact with the semiconductor layers 108C and the substrate 102 direct under the dummy gate structures 118 and the gate spacers 124. Furthermore, the dielectric layers 132 are separated from the (bottommost) semiconductor layers 106 by the semiconductor layers 108C.

Referring to FIGS. 34A and 34B, similar to FIGS. 24A and 24B, the sequent processes discussed above are performed on the workpiece 100 shown in FIG. 33 to form the CFETs 200A and 200B. The semiconductor layers 108C may also be referred to as nanostructures 108C, similar to the semiconductor layers 108A and 108B. As shown in FIGS. 34A and 34B, the semiconductor layers 108C are over and in contact with the dielectric layers 132, and under and in contact with the gate structure 160 (specifically, the gate dielectric layer 156). In other words, the semiconductor layers 108C are vertically between and in contact with the gate structure 160 (specifically, the gate dielectric layer 156) and the dielectric layers 132 in the Z-direction.

Furthermore, the bottom dielectric layers 144 are disposed on opposite sides of the semiconductor layers 108C, as shown in FIG. 34A. More specifically, the bottom dielectric layers 144 are in contact with (the sidewalls of) the semiconductor layers 108C in the X-direction. In some embodiments, the semiconductor layers 108C is separated and electrically isolated from the source/drain features 146P by the bottom dielectric layers 144. Therefore, the semiconductor layers 108C are electrically nonfunctional. In some embodiments, the gate structure 160 (specifically, the gate dielectric layer 156) and the isolation feature 116 are disposed in contact with (the sidewalls of) the semiconductor layers 108C in the Y-direction, as shown in FIG. 34B.

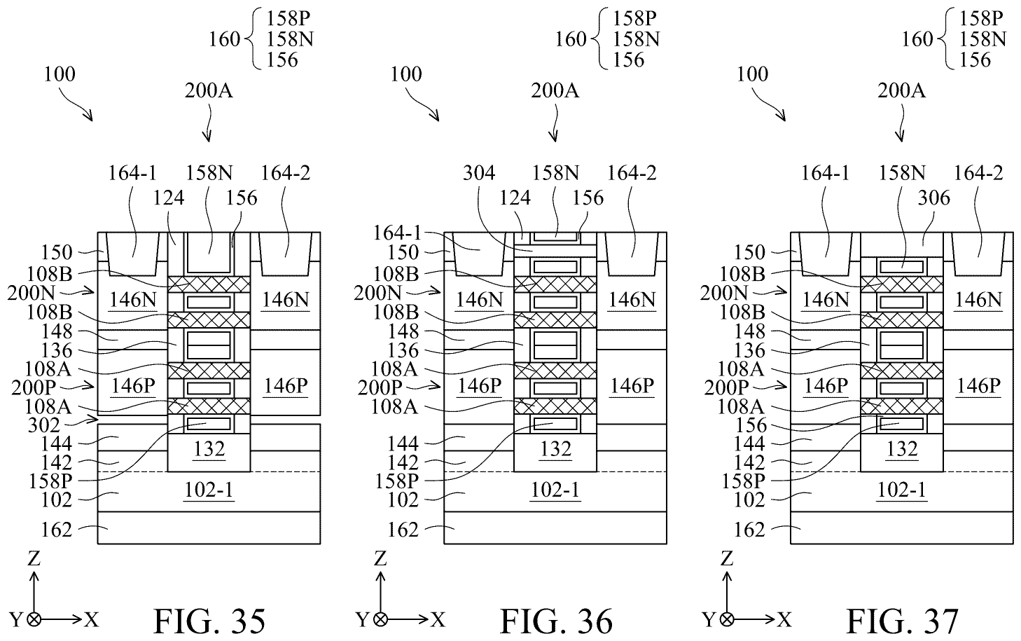

FIGS. 35, 36, and 37 are X-Z cross-sectional views of the workpiece 100 at the fabrication stage shown in FIG. 25A, in accordance with some alternative embodiments of the present disclosure. The workpiece 100 shown in FIG. 35 is similar to the workpiece 100 shown in FIG. 25A, except that the workpiece 100 shown in FIG. 35 further includes air gaps 302. More specifically, the formation of the source/drain features 146P is controlled, such that the source/drain features 146P is formed partially fill the lower parts of the source/drain trenches 126, thereby forming the air gaps 302 under the source/drain features 146P. In some aspects, the air gaps 302 are formed vertically between the source/drain features 146P and the bottom dielectric layers 144 in the Z-direction. Therefore, the source/drain features 146P are vertically separated from the bottom dielectric layers 144 by the air gaps 302 in the Z-direction. Such air gaps 302 may further increase the isolation of the source/drain features 146P from the substrate 102.

The workpiece 100 shown in FIG. 36 is similar to the workpiece 100 shown in FIG. 25A, except that the workpiece 100 shown in FIG. 35 further includes a dielectric layer 304. The dielectric layer 304 is disposed over the semiconductor layers 108 and the dielectric layer 132. In some embodiments, the dielectric layer 304 is vertically between the gate spacers 124 and the inner spacers 136 in the Z-direction, as shown in FIG. 36. Furthermore, the dielectric layer 304 is also wrapped around by the gate structure 160, similar to the semiconductor layers 108. As shown in FIG. 36, a bottom surface of the dielectric layer 304 is higher than the top surfaces of the source/drain features 146N.

The workpiece 100 shown in FIG. 37 is similar to the workpiece 100 shown in FIG. 25A, except that the workpiece 100 shown in FIG. 35 further includes a dielectric layer 306. The dielectric layer 306 is similar to the dielectric layer 304 shown in FIG. 36. As shown in FIG. 37A, a top surface of the dielectric layer 306 is substantially level with the top surfaces of the CESLs 150. The dielectric layer 306 is disposed over the semiconductor layers 108, the dielectric layer 132, and the gate structure 160. In these embodiments, the gate spacers 124 and a portion of the gate structure 160 over the dielectric layer 306 are removed.

In the embodiments shown in FIGS. 36 and 37, the dielectric layers 304 and 306 occupy a portion of the gate structure 160, such that a volume of the gate structure 160 is reduced, thereby reducing the parasitic capacitance induced by the gate structure 160 to other conductive features.

The embodiments disclosed herein relate to semiconductor structures and their manufacturing methods, and more particularly to methods and semiconductor structures including CFET with a dielectric layer under a gate structure and nanostructures. Furthermore, the present embodiments provide one or more of the following advantages. The dielectric layer under the gate structure and the nanostructures in the CFET reduce the parasitic capacitance between the gate structure and the substrate, thereby improving the performance of the CFET.

Thus, one of the embodiments of the present disclosure describes a semiconductor structure that includes first transistor, second transistor, a gate structure, and a first dielectric layer. The first transistor is over a substrate. The first transistor includes first nanostructures spaced apart from each other in a Z-direction, and first source/drain features on opposite sides of the first nanostructures in an X-direction. The second transistor is over the first transistor. The second transistor includes second nanostructures spaced apart from each other in the Z-direction, and second source/drain features on opposite sides of the second nanostructures in the X-direction. The second nanostructures are over the first nanostructures. The second source/drain features are over the first source/drain features. The gate structure wraps around the first nanostructures and the second nanostructures. The first dielectric layer is under the gate structure, the first nanostructures, and the second nanostructures.

In some embodiments, a thickness of the first dielectric layer is in a range from about 3 nm to about 15 nm.

In some embodiments, a material of the first dielectric layer comprises Si₃N₄, SiO₂, SiON, SiCN, SiCON, or SiOC.

In some embodiments, a width of the first source/drain features and the second source/drain features in the X-direction is greater than a thickness of the first dielectric layer in the Z-direction.

In some embodiments, the semiconductor structure further includes silicon layers over the substrate and under the first source/drain features, wherein the silicon layers are in contact with sidewalls of the first dielectric layer in the X-direction.

In some embodiments, bottom surfaces of the silicon layers are non-planar.

In some embodiments, the semiconductor structure further includes bottom dielectric layers over the silicon layers and under the first source/drain features, wherein bottom dielectric layers are in contact with sidewalls of the first dielectric layer in the X-direction.

In some embodiments, the first source/drain features are vertically separated from the bottom dielectric layers.

In some embodiments, the semiconductor structure further includes a third nanostructure between and in contact with the gate structure and the first dielectric layer.

In some embodiments, the semiconductor structure further includes a second dielectric layer over the first nanostructures and the second nanostructures.

In another of the embodiments, discussed is a semiconductor structure including a first transistor, a second transistor, a gate dielectric layer, a first work function metal layer, a second work function metal layer, and a dielectric layer. The first transistor is over a substrate. The first transistor includes first nanostructures over a substrate, and first source/drain features attached to the first nanostructures in an X-direction. The first nanostructures are spaced apart from each other in a Z-direction. The second transistor is over the first transistor. The second transistor includes second nanostructures over the first nanostructures, and second source/drain features attached to the second nanostructures in the X-direction. The second nanostructures are spaced apart from each other in the Z-direction. The second source/drain features are over the first source/drain features. The gate dielectric layer wraps around the first nanostructures and the second nanostructures. The first work function metal layer wraps around the gate dielectric layer and the first nanostructures. The second work function metal layer wraps around the gate dielectric layer and the second nanostructures. The dielectric layer is under the first work function metal layer and the second work function metal layer.

In some embodiments, the semiconductor structure further includes a third nanostructure over and in contact with the dielectric layer.

In some embodiments, the semiconductor structure further includes silicon layers in contact with and on opposite sides of the dielectric layer in the X-direction.

In some embodiments, the semiconductor structure further includes bottom dielectric layers over the silicon layers, wherein bottom dielectric layers are in contact with sidewalls of the third nanostructure in the X-direction.

In some embodiments, the semiconductor structure further includes air gaps under the first source/drain features.

In some embodiments, the first source/drain features are in contact with sidewalls of the dielectric layer.

In yet another of the embodiments, discussed is a method for manufacturing a semiconductor structure including forming a fin over a substrate in a Z-direction. The fin includes first semiconductor layers, second semiconductor layers alternately stacked with the first semiconductor layers, and a third semiconductor layer under the first semiconductor layers and the second semiconductor layers. The second semiconductor layers include a first group and a second group over the first group. The method further includes forming a dummy gate structure over the fin, replacing the third semiconductor layer with a dielectric layer, forming first source/drain features on opposite sides of the dummy gate structure and attached to the first group of the second semiconductor layers in an X-direction, forming second source/drain features on opposite sides of the dummy gate structure and attached to the second group of the second semiconductor layers in the X-direction, removing the dummy gate structure and the first semiconductor layers in the fin to form a gate trench, and forming a gate structure in the gate trench to wrap around the second semiconductor layers. The second source/drain features are over the first source/drain features. The dielectric layer is under and in contact with the gate structure.

In some embodiments, the replacement of the third semiconductor layer with a dielectric layer includes recessing portions of the fin to form source/drain trenches exposing sidewalls of the third semiconductor layer in the X-direction, removing the third semiconductor layer through the source/drain trenches to form a gap, forming a dielectric material filling the gap and partially filling the source/drain trenches, and removing the dielectric material in the source/drain trenches.

In some embodiments, a width of the source/drain trenches in the X-direction is greater than a dimension of the gap in the Z-direction.

In some embodiments, the method further includes forming silicon layers in the source/drain trenches and in contact with the dielectric layer in the X-direction, and forming bottom dielectric layers over the silicon layers and in contact with the dielectric layer in the X-direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor over a substrate, comprising:
first nanostructures spaced apart from each other in a Z-direction; and
first source/drain features on opposite sides of the first nanostructures in an X-direction; and
a second transistor over the first transistor, comprising:
second nanostructures spaced apart from each other in the Z-direction, wherein the second nanostructures are over the first nanostructures; and
second source/drain features on opposite sides of the second nanostructures in the X-direction, wherein the second source/drain features are over the first source/drain features;
a gate structure wrapping around the first nanostructures and the second nanostructures; and
a first dielectric layer under the gate structure, the first nanostructures, and the second nanostructures.

2. The semiconductor structure of claim 1, wherein a thickness of the first dielectric layer is in a range from about 3 nm to about 15 nm.

3. The semiconductor structure of claim 1, wherein a material of the first dielectric layer comprises Si₃N₄, SiO₂, SiON, SiCN, SiCON, or SiOC.

4. The semiconductor structure of claim 1, wherein a width of the first source/drain features and the second source/drain features in the X-direction is greater than a thickness of the first dielectric layer in the Z-direction.

5. The semiconductor structure of claim 1, further comprising:
silicon layers over the substrate and under the first source/drain features, wherein the silicon layers are in contact with sidewalls of the first dielectric layer in the X-direction.

6. The semiconductor structure of claim 5, wherein bottom surfaces of the silicon layers are non-planar.

7. The semiconductor structure of claim 5, further comprising:
bottom dielectric layers over the silicon layers and under the first source/drain features, wherein bottom dielectric layers are in contact with sidewalls of the first dielectric layer in the X-direction.

8. The semiconductor structure of claim 7, wherein the first source/drain features are vertically separated from the bottom dielectric layers.

9. The semiconductor structure of claim 1, further comprising:
a third nanostructure between and in contact with the gate structure and the first dielectric layer.

10. The semiconductor structure of claim 1, further comprising:
a second dielectric layer over the first nanostructures and the second nanostructures.

11. A semiconductor structure, comprising:
a first transistor over a substrate, comprising:
first nanostructures over a substrate, wherein the first nanostructures are spaced apart from each other in a Z-direction; and
first source/drain features attached to the first nanostructures in an X-direction; and
a second transistor over the first transistor, comprising:
second nanostructures over the first nanostructures, wherein the second nanostructures are spaced apart from each other in the Z-direction; and
second source/drain features attached to the second nanostructures in the X-direction, wherein the second source/drain features are over the first source/drain features; and
a gate dielectric layer wrapping around the first nanostructures and the second nanostructures;
a first work function metal layer wrapping around the gate dielectric layer and the first nanostructures;
a second work function metal layer wrapping around the gate dielectric layer and the second nanostructures; and
a dielectric layer under the first work function metal layer and the second work function metal layer.

12. The semiconductor structure of claim 11, further comprising:
a third nanostructure over and in contact with the dielectric layer.

13. The semiconductor structure of claim 12, further comprising:
silicon layers in contact with and on opposite sides of the dielectric layer in the X-direction.

14. The semiconductor structure of claim 13, further comprising:
bottom dielectric layers over the silicon layers, wherein bottom dielectric layers are in contact with sidewalls of the third nanostructure in the X-direction.

15. The semiconductor structure of claim 11, further comprising:
air gaps under the first source/drain features.

16. The semiconductor structure of claim 11, wherein the first source/drain features are in contact with sidewalls of the dielectric layer.

17. A method for manufacturing a semiconductor structure, comprising:
forming a fin over a substrate in a Z-direction, wherein the fin comprises first semiconductor layers, second semiconductor layers alternately stacked with the first semiconductor layers, and a third semiconductor layer under the first semiconductor layers and the second semiconductor layers, wherein the second semiconductor layers comprise a first group and a second group over the first group;
forming a dummy gate structure over the fin;
replacing the third semiconductor layer with a dielectric layer;
forming first source/drain features on opposite sides of the dummy gate structure and attached to the first group of the second semiconductor layers in an X-direction;
forming second source/drain features on opposite sides of the dummy gate structure and attached to the second group of the second semiconductor layers in the X-direction, wherein the second source/drain features are over the first source/drain features;
removing the dummy gate structure and the first semiconductor layers in the fin to form a gate trench; and
forming a gate structure in the gate trench to wrap around the second semiconductor layers, wherein the dielectric layer is under and in contact with the gate structure.

18. The method of claim 17, wherein the replacement of the third semiconductor layer with a dielectric layer comprises:
recessing portions of the fin to form source/drain trenches exposing sidewalls of the third semiconductor layer in the X-direction;
removing the third semiconductor layer through the source/drain trenches to form a gap;
forming a dielectric material filling the gap and partially filling the source/drain trenches; and
removing the dielectric material in the source/drain trenches.

19. The method of claim 18, wherein a width of the source/drain trenches in the X-direction is greater than a dimension of the gap in the Z-direction.

20. The method of claim 19, further comprising:
forming silicon layers in the source/drain trenches and in contact with the dielectric layer in the X-direction; and
forming bottom dielectric layers over the silicon layers and in contact with the dielectric layer in the X-direction.
